(19) United States
(12) Patent Application Publication
(10) Pub. No.: US 2026/0190321 A1
(43) Pub. Date: Jul. 2, 2026

(54) 3D MEMORY CELLS AND ARRAY ARCHITECTURES

(71) Applicant: NEO Semiconductor, Inc., San Jose, CA (US)

(72) Inventor: Fu-Chang Hsu, San Jose, CA (US)

(21) Appl. No.: 19/543,796

(22) Filed: Feb. 18, 2026

Related U.S. Application Data
(62) Division of application No. 18/311,167, filed on May 2, 2023.
Application No. 18/311,167 is a continuation-in-part of application No. 17/937,432, filed on Sep. 30, 2022.
(60) Provisional application No. 63/251,583, filed on Oct. 1, 2021.
(60) Provisional application No. 63/254,841, filed on Oct. 12, 2021.
(60) Provisional application No. 63/291,380, filed on Dec. 18, 2021.
(60) Provisional application No. 63/295,874, filed on Jan. 1, 2022.
(60) Provisional application No. 63/398,807, filed on Aug. 17, 2022.
(60) Provisional application No. 63/398,807, filed on Aug. 17, 2022.
(60) Provisional application No. 63/406,255, filed on Sep. 14, 2022.
(60) Provisional application No. 63/413,493, filed on Oct. 5, 2022.
(60) Provisional application No. 63/418,698, filed on Oct. 24, 2022.
(60) Provisional application No. 63/440,695, filed on Jan. 24, 2023.
(60) Provisional application No. 63/442,528, filed on Feb. 1, 2023.
(60) Provisional application No. 63/444,205, filed on Feb. 8, 2023.
(60) Provisional application No. 63/444,551, filed on Feb. 9, 2023.
(60) Provisional application No. 63/451,624, filed on Mar. 12, 2023.

(51) Int. Cl. H10B 12/00; H10B 41/20; H10B 43/10; H10B 51/20; H10B 61/00; H10B 63/10; H10N 50/85; H10N 70/00

(52) U.S. Cl. CPC H10B 12/20; H10B 12/01; H10B 41/20; H10B 43/10; H10B 51/20; H10B 61/22; H10B 63/10; H10N 50/85; H10N 70/8828

(57) ABSTRACT

Various three-dimensional memory cell structures, array architectures, and fabrication processes are disclosed. In an example process, first and second sacrificial layers having different etch selectivities are alternately deposited to form a multilayer stack, and vertical openings are etched through the stack. Portions of the first sacrificial layers are selectively removed through the openings to form lateral recesses. Semiconductor material is deposited to fill the lateral recesses and the vertical openings and is anisotropically etched to re-form the vertical openings while retaining semiconductor material in the recesses as channel regions. The re-formed openings are filled with conductor material to form vertical bit lines coupled to the channel regions. The first sacrificial layers are removed, and the resulting spaces are filled to form a source line layer, and the second sacrificial layers are removed to form spaces in which gate dielectric and gate conductor materials are formed adjacent to the channel regions.

### CLAIM TO PRIORITY

This application is a Divisional Application of U.S. patent application Ser. No. 18/311,167 filed on May 2, 2023.

The application Ser. No. 18/311,167 is a continuation-in-part (CIP) of U.S. patent application Ser. No. having Application Ser. No. 17/937,432 filed on Sep. 30, 2022, and entitled “3D Memory Cells and Array Architectures.”

The application Ser. No. 18/311,167 claims the benefit of priority under 35 U.S.C. 119(e) based upon U.S. Provisional Patent Application having Application No. 63/398,807 filed on Aug. 17, 2022, and entitled “Memory Cell and Array Architectures and Operation Conditions,” and U.S. Provisional Patent Application having Application No. 63/406,255 filed on Sep. 14, 2022, and entitled “3D Cell and Array Structures,” and U.S. Provisional Patent Application having Application No. 63/413,493 filed on Oct. 5, 2022, and entitled “3D Cell and Array Structures,” and U.S. Provisional Patent Application having Application No. 63/418,698 filed on Oct. 24, 2022, and entitled “3D Cell and Array Structures,” and U.S. Provisional Patent Application having Application No. 63/440,695 filed on Jan. 24, 2023, and entitled “3D Cell and Array Structures,” and U.S. Provisional Patent Application having Application No. 63/442,528 filed on Feb. 1, 2023, and entitled “3D Cell and Array Structures,” and U.S. Provisional Patent Application having Application No. 63/444,205 filed on Feb. 8, 2023, and entitled “3D Cell and Array Structures,” and U.S. Provisional Patent Application having Application No. 63/444,551 filed on Feb. 9, 2023, and entitled “3D Cell and Array Structures,” and U.S. Provisional Patent Application having Application No. 63/451,624 filed on Mar. 12, 2023, and entitled “3D Cell and Array Structures and Processes,” all of which are hereby incorporated herein by reference in their entireties.

The application Ser. No. 17/937,432 claims the benefit of priority under 35 U.S.C. 119(e) based upon U.S. Provisional Patent Application having Application No. 63/398,807 filed on Aug. 17, 2022, and entitled “Memory Cell and Array Architectures and Operation Conditions,” and U.S. Provisional Patent Application having Application No. 63/295,874 filed on Jan. 1, 2022, and entitled “Alpha-RAM (a-RAM) or Alpha-DRAM (a-DRAM) Technology,” and U.S. Provisional Patent Application having Application No. 63/291,380 filed on Dec. 18, 2021 and entitled “3D DRAM-replacement Technologies,” and U.S. Provisional Patent Application having Application No. 63/254,841, filed on Oct. 12, 2021 and entitled “3D DRAM-replacement Technologies,” and U.S. Provisional Patent Application having Application No. 63/251,583 filed on Oct. 1, 2021 and entitled “3D DRAM-replacement Technologies,” all of which are hereby incorporated herein by reference in their entireties.

### CROSS REFERENCE TO RELATED APPLICATIONS

This application is related to the following co-pending U.S. patent application Ser No. having application Ser. No. 18/311,212 and Attorney Docket No. SIONS. PT9.CIP2, which was filed on May 2, 2023 and entitled “3D MEMORY CELLS AND ARRAY ARCHITECTURES AND PROCESSES.”

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use three-dimensional (3D) array structure. The 3D array structure has been successfully used in NAND flash memory today. However, for dynamic random-access memory (DRAM), due to its special one-transistor-one-capacitor (1T1C) cell structure, a cost-effective 3D array structure has not been realized.

### SUMMARY

In various exemplary embodiments, three-dimensional (3D) memory cells, array structures, and associated processes are disclosed. In one embodiment, a novel 3D array structure using floating-body cells to implement DRAM is disclosed. The array structure is formed using a deep trench process similar to 3D NAND flash memory. Therefore, ultra-high-density DRAM can be realized. In one embodiment, 3D NOR-type memory cells and array structures are provided. The disclosed memory cells and array structures are applicable to many technologies. For example, the inventive memory cells and array structures are applicable to dynamic random-access memory (DRAM), floating-body cell (FBC) memory, NOR-type flash memory, and thyristors.

In one embodiment, a memory cell structure is formed by alternately depositing first and second sacrificial layers having different etch selectivities to form a multilayer stack, etching vertical openings through the stack, and selectively removing portions of the first sacrificial layers through the openings to form lateral recesses. Semiconductor material is deposited to fill the recesses and the openings and is anisotropically etched to re-form the vertical openings while retaining semiconductor material in the recesses as junction-less floating-body channel regions. The re-formed openings are filled with conductor material to form vertical bit lines, the first sacrificial layers are removed and corresponding spaces are filled to form a source line layer, and the second sacrificial layers are removed to form spaces in which gate dielectric and gate conductor materials are formed adjacent to the channel regions.

In some embodiments, the resulting structure forms a three-dimensional array of junction-less floating-body transistors in which laterally-extending channel regions are defined within recesses between sacrificial layers, vertical conductive bit lines extend through the stack to contact the channel regions, and a conductive source line layer is formed in first spaces created by removing first sacrificial layers. After removing second sacrificial layers, gate dielectric and gate conductor materials are formed in second spaces adjacent to the channel regions to provide gate structures that surround the channel regions and enable stacked memory cells at different vertical levels.

In an exemplary embodiment, a memory cell structure is provided that includes a first semiconductor material, a floating body semiconductor material having an internal side surface that surrounds and connects to the first semiconductor material, and a second semiconductor material having an internal side surface that surrounds and connects to the floating body semiconductor material. The memory cell structure also includes a first dielectric layer connected to a top surface of the floating body material, a second dielectric layer connected to a bottom surface of the floating body material, a front gate connected to the first dielectric layer, and a back gate connected to the second dielectric layer.

In an exemplary embodiment, a three-dimensional (3D) memory array is provided that comprises a plurality of memory cells separated by a dielectric layer to form a stack of memory cells. Each memory cell in the stack of memory cells comprises a bit line formed from one of a first semiconductor material and a first conductor material, a floating body semiconductor material having an internal side surface that surrounds and connects to the bit line, a source line formed from one of a second semiconductor material and a second conductor material having an internal side surface that surrounds and connects to the floating body semiconductor material, and a word line formed from a third conductor material that is coupled to the floating body semiconductor through the dielectric layer to form a gate of the memory cell. Additionally, the bit lines of the stack of memory cells are connected to form a vertical bit line.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A shows an embodiment of a cell structure for a three-dimensional (3D) NOR-type array constructed according to the invention.

FIG. 1B shows an embodiment of an inner cell structure of the cell shown in FIG. 1A.

FIG. 1C shows another embodiment of a cell structure constructed according to the invention.

FIG. 1D shows the cell structure of FIG. 1C with selected portions removed.

FIG. 1E shows another embodiment of a cell structure constructed according to the invention.

FIG. 1F shows the inner cell structure of the cell shown in FIG. 1E with selected portions removed.

FIG. 1G shows another embodiment of a cell structure constructed according to the invention.

FIG. 1H shows the inner cell structure of the cell shown in FIG. 1G with selected portions removed.

FIG. 1I shows another embodiment of a cell structure constructed according to the invention.

FIG. 1J shows the inner cell structure of the cell shown in FIG. 1I with selected portions removed.

FIG. 1K shows another embodiment of a cell structure constructed using a junction-less thin-film transistor according to the invention.

FIG. 1L shows an embodiment of a cross-section view of the cell structure shown in FIG. 1K.

FIG. 1M shows an exemplary embodiment of a three-dimensional (3D) NOR-type memory cell structure using a floating body cell (FBC) configuration in accordance with the invention.

FIG. 1N shows the cell structure shown in FIG. 1M with a front gate and a gate dielectric layer removed.

FIG. 1O shows a cell formed using a PMOS transistor.

FIG. 1P shows an embodiment of an array structure based on the cell structure shown in FIG. 1M.

FIG. 1Q shows another embodiment of an array structure according to the invention.

FIG. 1R shows an equivalent circuit diagram for the array structure shown in FIG. 1P.

FIG. 1S shows another embodiment of an equivalent circuit diagram of the array structure shown in FIG. 1P.

FIG. 2A shows another embodiment of a cell structure for 3D NOR-type flash memory constructed according to the invention.

FIG. 2B shows an inner cell structure of the cell shown in FIG. 2A with selected portions removed.

FIG. 2C shows another embodiment of a cell structure for 3D non-volatile random-access memory constructed according to the invention.

FIG. 2D shows an inner cell structure of the embodiment shown in FIG. 2C with selected portions removed.

FIGS. 3A-B show embodiments of a 3D array structure constructed according to the invention.

FIGS. 4A-F show embodiments of brief process steps used to form the floating-body cell structure shown in FIGS. 1A-B according to the invention.

FIGS. 4G-H show another embodiment of brief process steps used to form the cell structure of the 3D NOR-type flash memory shown in FIGS. 2A-B.

FIGS. 5A-H show embodiments of brief process steps to form the floating-body cell structure shown in FIGS. 1C-D according to the invention.

FIGS. 5I-J show another embodiment of brief process steps used to form the cell structure of a 3D NOR-type flash memory.

FIGS. 6A-B show another embodiment of brief process steps to form the junction-less floating-body cell structure shown in FIGS. 1I-J according to the invention.

FIG. 6C shows how recesses and vertical bit line holes are filled with a semiconductor.

FIG. 6D shows how an anisotropic etching process is used to selectively etch a semiconductor to form the vertical bit line holes.

FIG. 6E shows how the vertical bit line holes are filled with high melting point metal to form the vertical bit lines.

FIG. 6F shows how first sacrificial layers are selectively removed by using an isotropic etching process.

FIG. 6G shows how a high melting point metal is deposited to form source line layers.

FIG. 6H shows how second sacrificial layers are selectively removed by using an isotropic etching process.

FIG. 6I shows how the process steps described with reference to FIGS. 4E-F are applied to form a gate dielectric layer.

FIG. 6J shows another embodiment for forming a junction-less transistor.

FIGS. 7A-M show another embodiment of brief process steps to form the cell structure shown in FIGS. 1G-H according to the invention.

FIG. 7N shows another embodiment of process steps to form a cell structure.

FIGS. 8A-K show another embodiment of brief process steps to form a cell structure comprising a thin-film transistor as shown in FIGS. 1K-L according to the invention.

FIG. 8L shows another embodiment for forming a cell structure.

FIGS. 9A-J show another embodiment of brief process steps to form the cell structure shown in FIGS. 1E-F according to the invention.

### DETAILED DESCRIPTION

Those of ordinary skill in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, three-dimensional (3D) memory cells, array structures, and associated processes are disclosed. For example, 3D NOR-type cells and array structures and processes are disclosed. The various embodiments of the invention can be applied to many technologies. For example, aspects of the invention can be applied to dynamic random-access memory (DRAM) using floating-body cells (FBC), NOR-type flash memory, Ferroelectric random-access memory (FRAM), resistive random-access memory (RRAM), phase change memory (PCM), magnetoresistive random-access memory (MRAM), and memory elements called ‘synapses’in in-memory computing or neural network arrays for artificial intelligence (AI) applications. In addition, embodiments of the invention are applicable to other memory applications not listed.

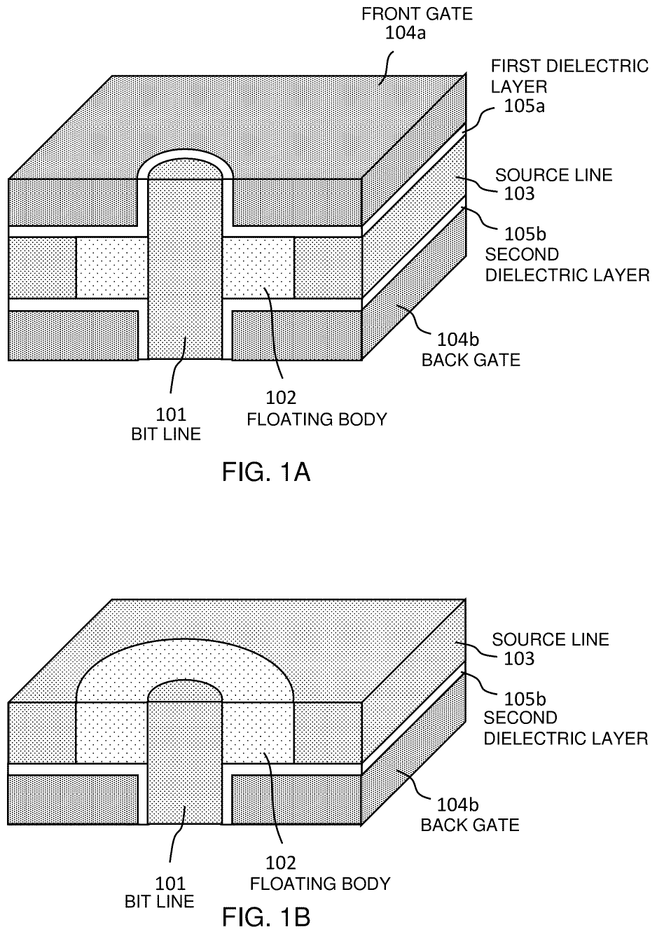

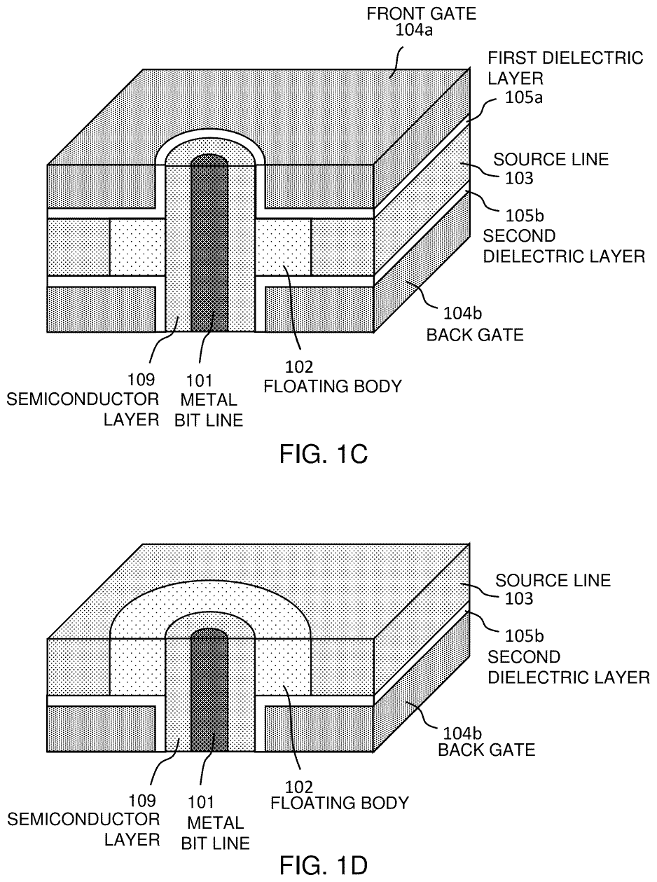

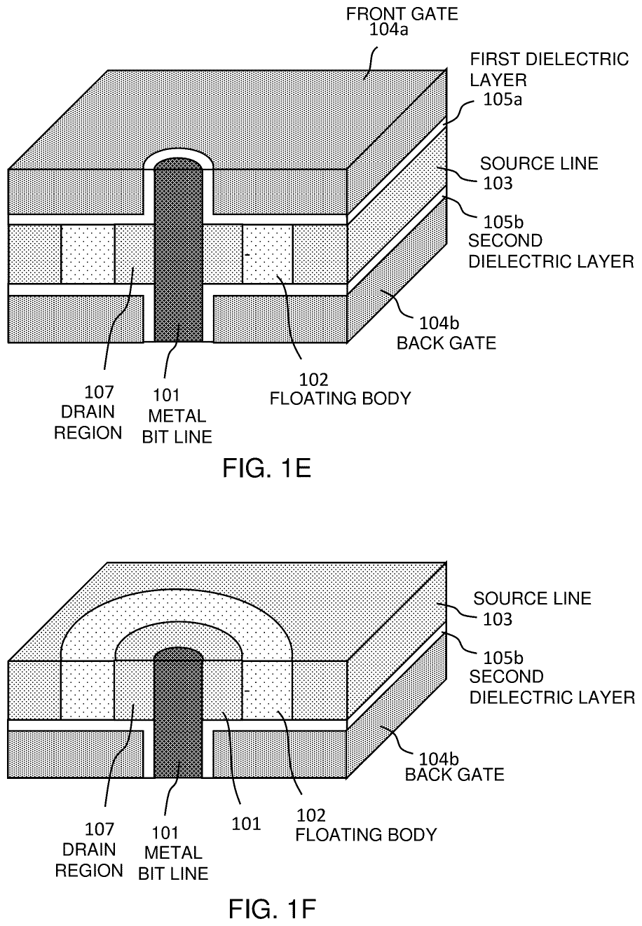

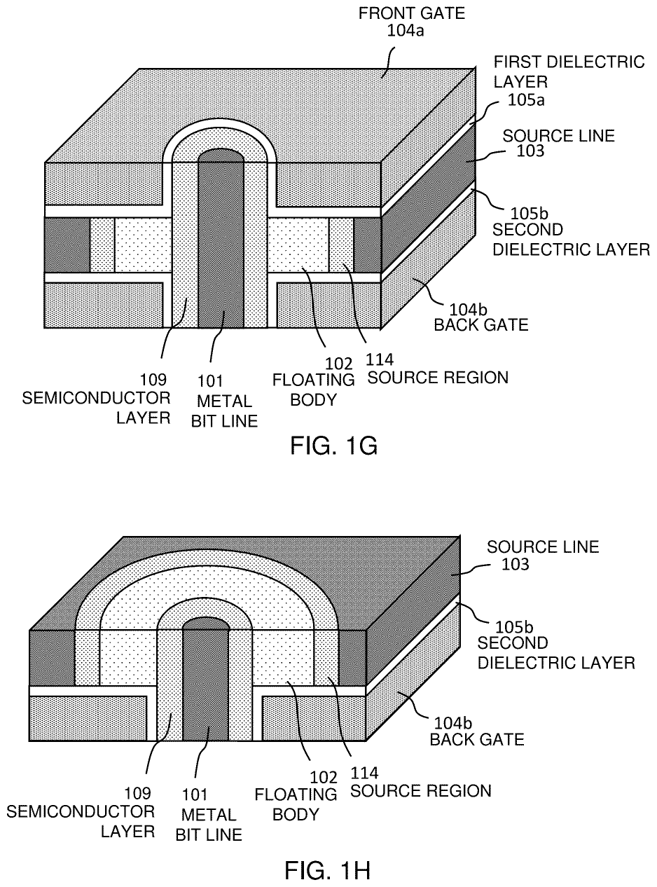

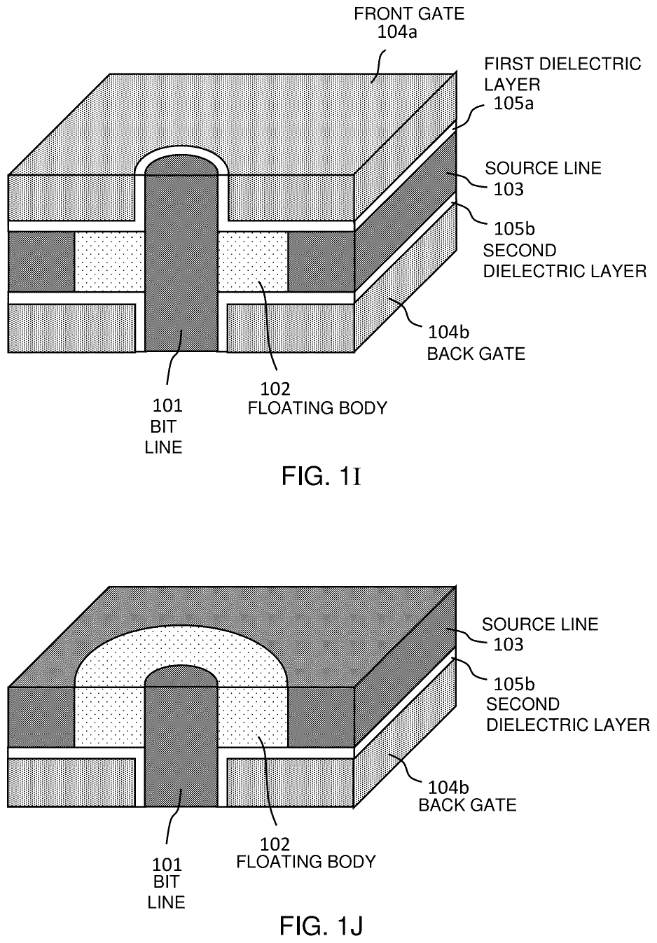

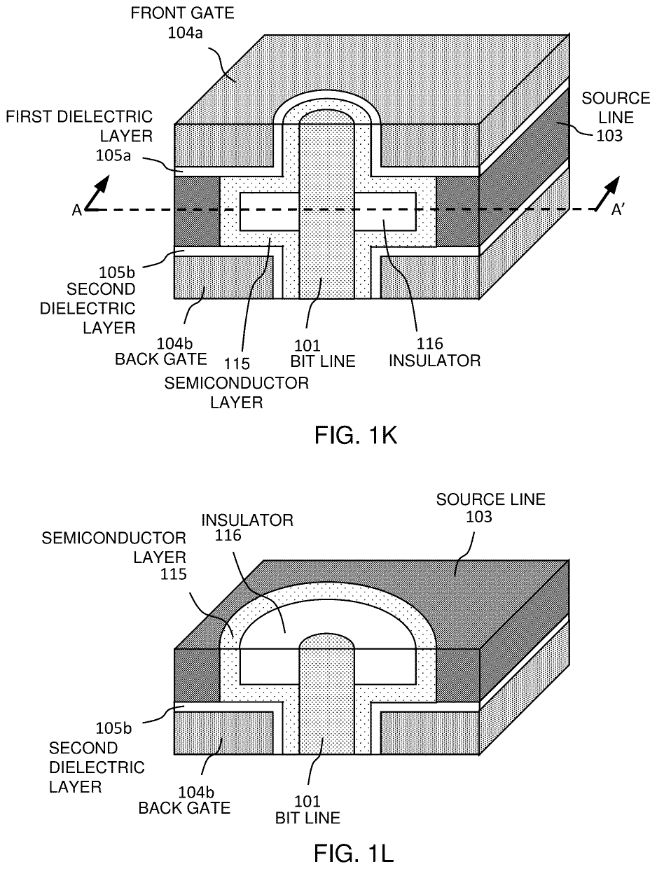

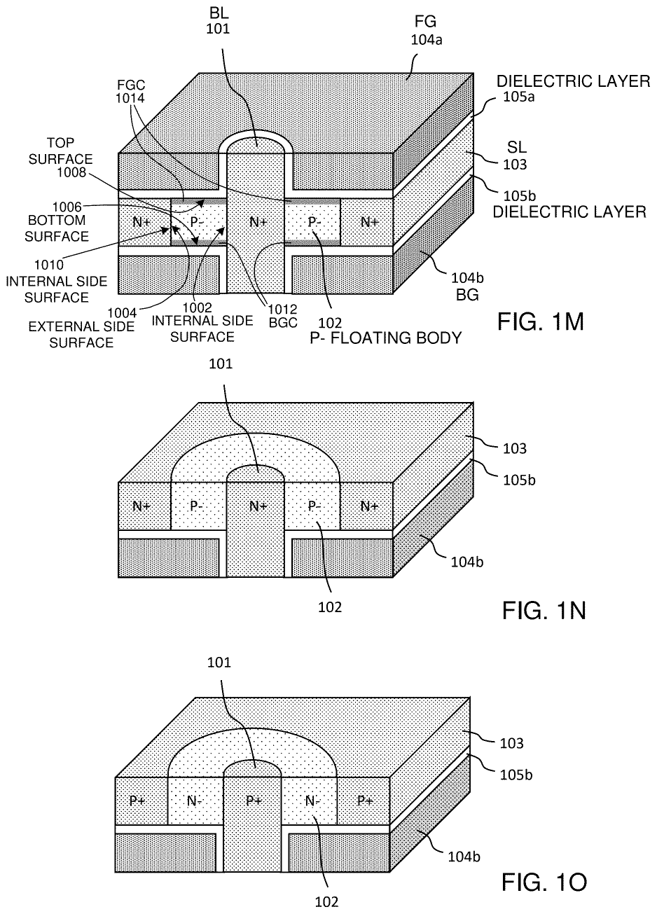

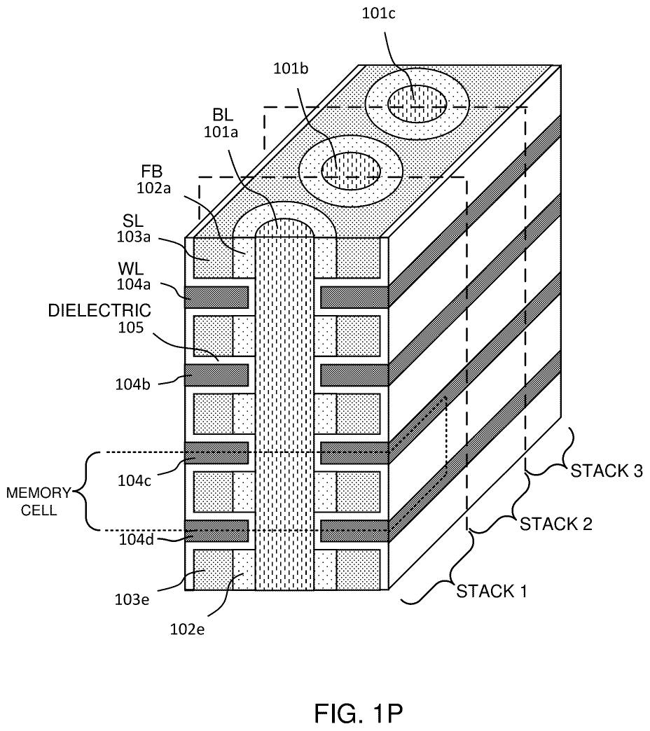

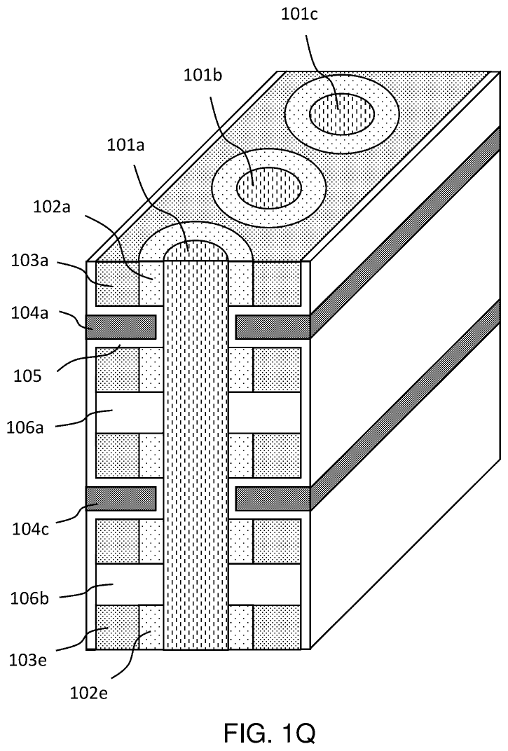

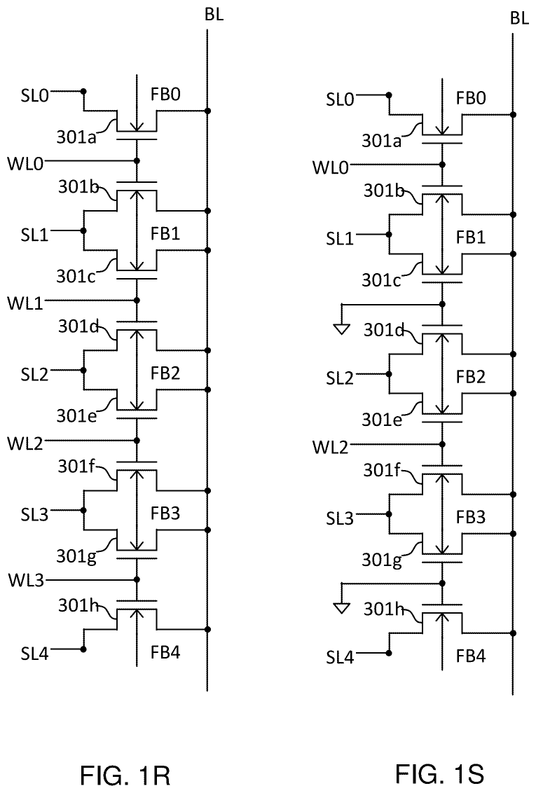

FIG. 1A shows an embodiment of a cell structure for a three-dimensional (3D) NOR-type array constructed according to the invention. The cell structure shown in FIG. 1A comprises a semiconductor layer that forms a vertical bit line (BL) 101 that comprises silicon or polysilicon, a floating body 102 formed of silicon or polysilicon and a horizontal source line (SL) 103 formed of silicon or polysilicon. The cell also comprises a front gate 104a, a back gate 104b, a first gate dielectric layer 105a, and a second gate dielectric layer 105b. In one embodiment, the gates 104a and 104b are formed of conductor material, such as metal or heavily doped polysilicon. The front gate 104a and back gate 104b can be connected to horizontal word lines (WL).

The cell can be formed as either an NMOS or PMOS transistor. For an NMOS cell embodiment, the bit line 101 and the source line 103 have N+ type of doping and the floating body 102 has P-type of doping. For the PMOS cell embodiment, the bit line 101 and the source line 103 have P+type of doping and the floating body 102 has N-type of doping.

FIG. 1B shows an embodiment of the inner cell structure of the cell shown in FIG. 1A with the front gate 104a, the gate dielectric layer 105a, and a portion of the BL 101 removed. Although the embodiments show that the shapes of the bit line 101 and floating body 102 are circular, in other embodiments, the bit line 101 and the floating body 102 can have any suitable shapes, such as square, rectangular, triangular, hexagon, etc. These variations are within the scope of the embodiments.

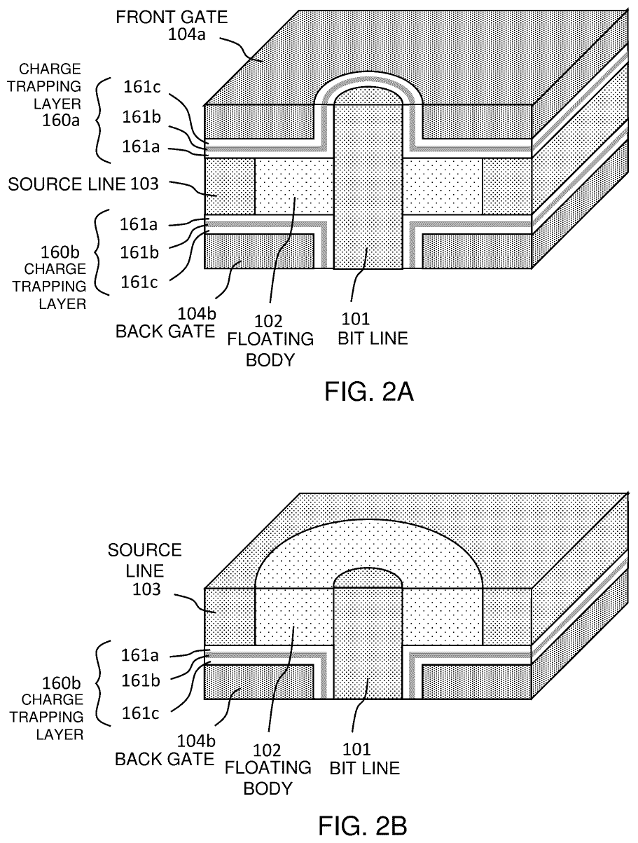

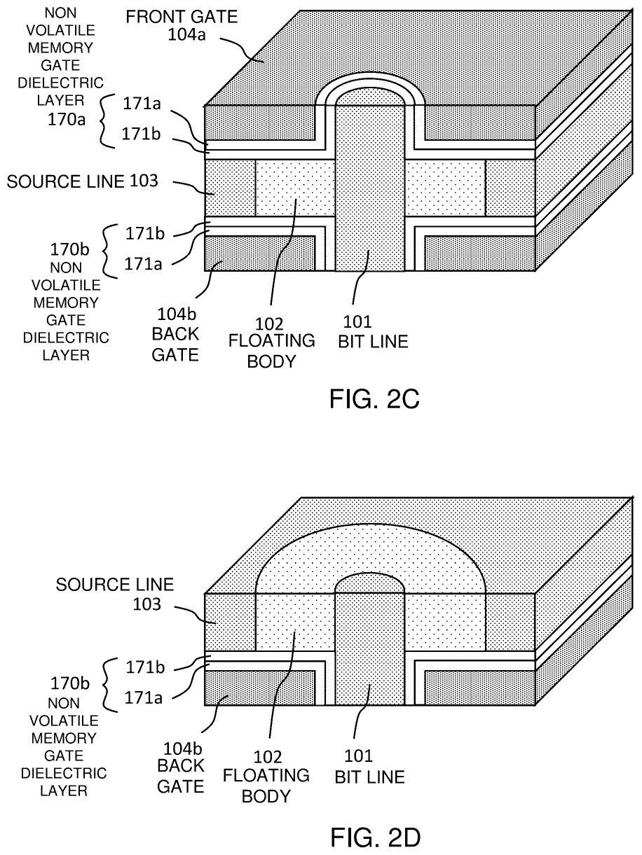

Depending on the cell types and technologies, the gate dielectric layers 105a and 105b can be formed of a variety of different materials and structures. For example, in one embodiment, the cell may be formed as a floating-body cell for DRAM application. For this embodiment, the gate dielectric layers 105a and 105b are thin gate oxide layers or high-K material layers, such as hafnium oxide (HfO2). In another embodiment, the gate dielectric layers 105a and 105b are formed from other suitable materials to form NOR-type flash memory, ferroelectric random-access memory (FRAM), resistive random-access memory (RRAM), phase-change memory (PCM), magnetoresistive random-access memory (MRAM), and others, as shown in FIGS. 2A-D.

FIG. 1C shows another embodiment of a cell structure constructed according to the invention. This embodiment is similar to the embodiment in FIG. 1A except that a metal vertical bit line 101 is formed of a metal core in the center of the semiconductor layer 109 to reduce the bit line resistance.

FIG. 1D shows the cell structure of FIG. 1C with the front gate 104a and gate dielectric layer 105a and a portion of the metal BL 101 and the semiconductor layer 109 removed.

FIG. 1E shows another embodiment of a cell structure constructed according to the invention. This embodiment is similar to the embodiments shown in FIGS. 1C-D except that a drain region 107 is formed around the side of the metal bit line 101 as shown. In an embodiment, the drain region 107 is formed of silicon or polysilicon with the opposite type of heavy doping as the doping of the floating body 102. For example, the ‘opposite type of doping’ means that P-type (positive) doping is the opposite of N-type (negative) doping. For example, if the floating body 102 comprises P-type doping, the drain region 107 comprises N-type doping, which is the opposite type of doping. If the floating body 102 comprises N-type doping, the drain region 107 comprises P-type doping, which is the opposite type of doping. The terms ‘heavy doping’ and ‘light doping’ are relative terms that describe the amount of doping. When a semiconductor is doped with excess electrons or holes, it is called a heavily doped semiconductor, indicated by N+or P+, respectively. When a semiconductor is doped with a small amount of electrons or holes, it is called a lightly doped semiconductor, indicated by N-or P-, respectively. As shown in FIG. 1E, the vertical bit line hole is filled with metal to form the metal bit line 101 to reduce the bit line resistance.

FIG. 1F shows the inner cell structure of the cell shown in FIG. 1E with the front gate 104a, the gate dielectric layer 105a, and a portion of the metal bit line 101 removed.

FIG. 1G shows another embodiment of a cell structure constructed according to the invention. This embodiment is similar to the embodiments shown in FIGS. 1C-D except that the source line 103 is formed of conductor material, such as metal to reduce the source line resistance. A source region 114 comprising semiconductor material, such as silicon or polysilicon, is formed between the metal source line 103 and the floating body 102. The source region 114 has the opposite type of heavy doping from the doping of the floating body 102.

FIG. 1H shows the inner cell structure of the cell shown in FIG. 1G with the front gate 104a and the gate dielectric layer 105a, and a portion of the metal BL 101 and the semiconductor layer 109 removed.

FIG. 1I shows another embodiment of a cell structure constructed according to the invention. This embodiment is similar to FIGS. 1A-B except that the bit line 101 and the source line 103 are formed of metal. A floating body 102 is formed of semiconductor material, such as silicon or polysilicon. In one embodiment, the floating body 102 has N+ or P+ type of heavy doping. This forms a junction-less cell transistor. In another embodiment, the floating body 102 has N− or P− type of light doping. This forms a Schottky-junction cell transistor.

FIG. 1J shows the inner cell structure of the cell shown in FIG. 1I with the front gate 104a, the gate dielectric layer 105a, and a portion of the BL 101 removed.

FIG. 1K shows another embodiment of a cell structure constructed using a junction-less thin-film transistor according to the invention. This embodiment is similar to the embodiments shown in FIGS. 1A-B except that a semiconductor layer 115 comprising silicon, polysilicon, germanium (Ge), indium gallium zinc oxide (IGZO), tungsten-doped indium oxide semiconductor, or any other suitable semiconductor material surrounds the BL 101 and an insulator 116 that comprises oxide or nitride. In one embodiment, the semiconductor layer 115 has N-type or P-type of heavy doping to form the channel of the cell transistor. In one embodiment, the bit line 101 and the source line 103 are formed of conductor material, such as metal or heavily doped polysilicon. FIG. 1K also shows a cross-section indicator A-A′.

FIG. 1L shows an embodiment of a cross-section view of the cell structure shown in FIG. 1K taken along the cross-section indicator A-A′.

FIG. 1M shows an exemplary embodiment of a three-dimensional (3D) NOR-type memory cell structure using a floating body cell (FBC) configuration in accordance with the invention. For example, a 3D NOR-type array can comprise multiple layers of floating-body cell arrays to increase the memory capacity. A floating-body cell is basically a transistor with floating body. The floating body stores electric charges, such as electrons or holes to represent the data. The cell structure comprises a control gate, a drain, a source, and a floating body. In the 3D memory array, the control gate, drain, and source of the cells are connected to a word line (WL), bit line (BL), and source line (SL), respectively.

In the cell structure shown in FIG. 1M, an N+ silicon or polysilicon forms a bit line (BL) 101 and a P-floating body 102 is used for charge storage. An N+silicon or polysilicon forms a source line (SL) 103. The cell may be formed as a dual-gate transistor shown in FIG. 1M or a single-gate transistor as shown in FIG. 1N. For the dual-gate transistor shown in FIG. 1M, the cell structure comprises two control gates called a front gate 104a and a back gate 104b, respectively. Both the front gate 104a and the back gate 104b are coupled to the floating body 102 through gate dielectric layers 105a and 105b, respectively. The gate dielectric layer is an insulating layer between the gate and the body of the transistor. When a proper voltage is applied to the front gate 104a or the back gate 104b, a front gate channel (FGC) 1014 or a back gate channel (BGC) 1012 are formed in the surface of the floating body 102 under the gate dielectric layer 105a and 105b to conduct current between the bit line 101 and source line 103. In an embodiment, the front gate 104a and back gate 104b are connected to different word lines (WL).

In an embodiment, the P-floating body 102 comprises multiple surfaces as shown in FIG. 1M. An internal side surface 1002 surrounds and connects to the BL 101. An external side surface 1004 connects to the source line 103. A top surface 1008 connects to the dielectric layer 105a, and a bottom surface 1006 connects to the dielectric layer 105b. Thus, in one embodiment, a memory cell structure is provided that includes a first semiconductor material BL 101, a floating body semiconductor material 102 having an internal side surface 1002 that surrounds and connects to the first semiconductor material BL 101, and a second semiconductor material SL 103 having an internal side surface 1010 that surrounds and connects to the floating body semiconductor material 102. The memory cell structure also includes a first dielectric layer 105a connected to a top surface 1008 of the floating body material 102, a second dielectric layer 105b connected to a bottom surface 1006 of the floating body material 102, a front gate 104a connected to the first dielectric layer 105a, and a back gate 104b connected to the second dielectric layer 105b. In various embodiments, minor modifications can be made to the disclosed structures, such as adding a lightly doped drain (LDD), halo implantation, pocket implantation, or channel implantation that are all included within the scope of the invention.

FIG. 1N shows the cell structure shown in FIG. 1M with the front gate 104a, the gate dielectric layer 105a, and a portion of the bit line 101 removed. The P-floating body 102 forms a donut shape as shown. Although this embodiment shows that the shapes for the bit line 101 and floating body 102 are circular, it is obvious that they can have any desired shape, such as square, rectangle, triangle, hexagon, etc. These variations shall remain in the scope of the invention.

In one embodiment, the cell structure comprises only one single gate, as shown in FIG. 1N. The floating body 102 is coupled to only one gate 104b as shown. An embodiment of a 3D array structure using this cell structure embodiment is shown in FIG. 1P.

The embodiment shown in FIG. 1M uses an NMOS transistor as the cell. In another embodiment, shown in FIG. 1O, the cell is formed using a PMOS transistor. The bit line 101, floating body 102, and source line 103 are formed by P+, N−, and P+ materials, respectively.

FIG. 1P shows an embodiment of an array structure based on the cell structure shown in FIG. 1M. The array structure comprises vertical bit lines 101a to 101c and floating bodies 102a to 102e. The array structure also comprises source lines 103a to 103e and word lines 104a to 104d. The array structure also includes dielectric layer 105 comprising a gate oxide or high-K material, such as HfO2.

In an embodiment, a three-dimensional (3D) memory array comprises a plurality of memory cells separated by a dielectric layer to form a stack of memory cells. For example, FIG. 1P shows a 3D array having three stacks of memory cells and a particular “memory cell” is identified. Each memory cell in the stack of memory cells comprises a bit line 101 formed from one of a first semiconductor material and a first conductor material, a floating body semiconductor material 102 having an internal side surface that surrounds and connects to the bit line, a source line 103 formed from one of a second semiconductor material and a second conductor material having an internal side surface that surrounds and connects to the floating body semiconductor material 102, and a word line 104 formed from a third conductor material that is coupled to the floating body semiconductor 102 through a dielectric layer 105 to form a gate of the memory cell. Additionally, the bit lines of the stack of memory cells are connected to form a vertical bit line (e.g., 101a).

FIG. 1Q shows another embodiment of an array structure according to the invention. This embodiment is similar to the embodiment shown in FIG. 1P except that the cells are single-gate transistors. Also shown in FIG. 1Q are insulating layers 106a and 106b that are formed from material, such as oxide.

FIG. 1R shows an equivalent circuit diagram for the array structure shown in FIG. 1P. For example, the equivalent circuit shows transistors 301a-h that are formed by the array structure shown in FIG. 1P. Referring again to the array structure in FIG. 1P, the word line structures 104a to 104d are connected to word lines WL0-WL3. The floating bodies structures 102a to 102e are the floating bodies FB0-FB4. The source line structures 103a to 103e are connected to the source lines SL0-SL4, and the bit line structure 101a is a vertical bit line (BL). In this embodiment, each floating body (e.g., FB0-FB4) is coupled to two word lines. This array requires special bias conditions for read and write operations to avoid two cells being selected at the same time.

FIG. 1S shows another embodiment of an equivalent circuit diagram of the array structure shown in FIG. 1P. This embodiment is similar to the embodiment shown in FIG. 1R except that the odd word lines, WL1, WL3, and so on, are connected to ground. This turns off the transistors 301c, 301d, 301g, and 301h. In this embodiment, each floating body is coupled to one word line only. However, the storage capacity of this embodiment is reduced to one half when compared with the embodiment shown in FIG. 1R.

FIG. 2A shows another embodiment of a cell structure for a 3D NOR-type flash memory constructed according to the invention. This embodiment is similar to the embodiments shown in FIGS. 1A-B except that the gate dielectric layers 105a and 105b are replaced with charge trapping layers 160a and 160b that comprise oxide-nitride-oxide (ONO) layers. In one embodiment, the charge trapping layer 160b comprises a tunnel oxide layer 161a that is thin enough to allow electrons to tunnel through when a high electric field is applied. This changes the threshold voltage of the cells to represent the stored data. A nitride layer 161b traps electrons for data storage. A blocking oxide 161c is thick enough to prevent electrons from tunneling through to the gates 104a and 104b. In another embodiment, the blocking oxide 161c comprises a tunnel oxide layer and the tunnel oxide layer 161a comprises a blocking oxide layer. In this embodiment, during programming, electrons are injected from a selected one of the gates 104a or 104b to the nitride layer 161b.

FIG. 2B shows the inner cell structure of the cell shown in FIG. 2A with the front gate 104a, the charge trapping layer 160a, and a portion of the BL 101 removed.

Although ONO layers 161a-c shown in FIG. 2B are used as an example for the charge-trapping layers 160a and 160b, in other embodiments, the charge-trapping layers 160a and 160b comprise any suitable number of oxide layers and nitride layers. For example, in another embodiment, the charge-trapping layers 160a and 160b comprise oxide-nitride-oxide-nitride-oxide (ONONO) layers. In another embodiment, the charge-trapping layers 160a and 160b comprise only one oxide and one nitride (ON) layers. These variations are within the scope of the embodiments.

In various embodiments, the charge-trapping layers 160a and 160b are also utilized in the other cell embodiments shown in FIGS. 1A-L to replace the gate dielectric layers 105a and 105b to form different types of NOR flash memory cells.

FIG. 2C shows another embodiment of a cell structure for 3D non-volatile random-access memory constructed according to the invention. This embodiment is similar to the embodiments shown in FIGS. 1A-B except that the gate dielectric layers 105a and 105b are replaced with non-volatile memory gate dielectric layers 170a and 170b. In one embodiment, the non-volatile memory gate dielectric layers 170a and 170b comprise multiple layers, such as 171a and 171b.

FIG. 2D shows the inner cell structure of the embodiment shown in FIG. 2C with the front gate 104a, the non-volatile memory gate dielectric layer 170a, and a portion of the BL 101 removed.

In one embodiment that forms a ferroelectric random-access memory (FRAM), the non-volatile memory gate dielectric layer 170b comprises a ferroelectric layer 171a, such as lead zirconate titanate (PZT) or hafnium oxide (HfO2) in orthorhombic crystal phase, or hafnium zirconium oxide (HfZrO2). The layer 171b comprises a dielectric layer, such as hafnium oxide (HfO2). When high voltages are applied to the gates 104a and 104b, the generated electric field alters the pole of the ferroelectric materials in the ferroelectric layer 171a to change the threshold voltage of the cells to represent the stored data.

In another embodiment that forms a resistive random-access memory (RRAM), the non-volatile memory gate dielectric layers 170a and 170b comprise an adjustable resistive layer 171a, such as hafnium oxide (HfOx), titanium oxide (TiOx), or tantalum oxide (TaOx), and a dielectric layer 171b, such as silicon oxide (SiO₂). In another embodiment that forms a phase-change memory (PCM), the non-volatile memory gate dielectric layers 170a and 170b are formed of multiple layers comprising at least one phase-change layer 171a, such as Germanium Antimony Tellurium alloy or chalcogenide glass, Ge2Sb2Te5 (GST), and a heater layer 171b, such as tungsten (W), titanium (Ti), or polysilicon.

In another embodiment, that forms a magnetoresistive random-access memory (MRAM), the non-volatile memory gate dielectric layers 170a and 170b comprise multiple layers including ferromagnetic material 171a and 171b, such as iron-nickel (NiFe) or iron-cobalt (CoFe) alloys, and a tunnel-barrier layer formed such as hafnium oxide (HfO₂) between the layers 171a and 171b. The materials of the non-volatile memory gate dielectric layers 170a and 170b described above are just some examples and any other suitable materials can be used for the non-volatile memory gate dielectric layers 170a and 170b within the scope of the embodiments.

The non-volatile memory gate dielectric layers 170a and 170b shown in this embodiment can be also utilized with all the other cell embodiments shown in FIG. 1A-L to replace the gate dielectric layers 105a and 105b to form various types of non-volatile random-access memory cells.

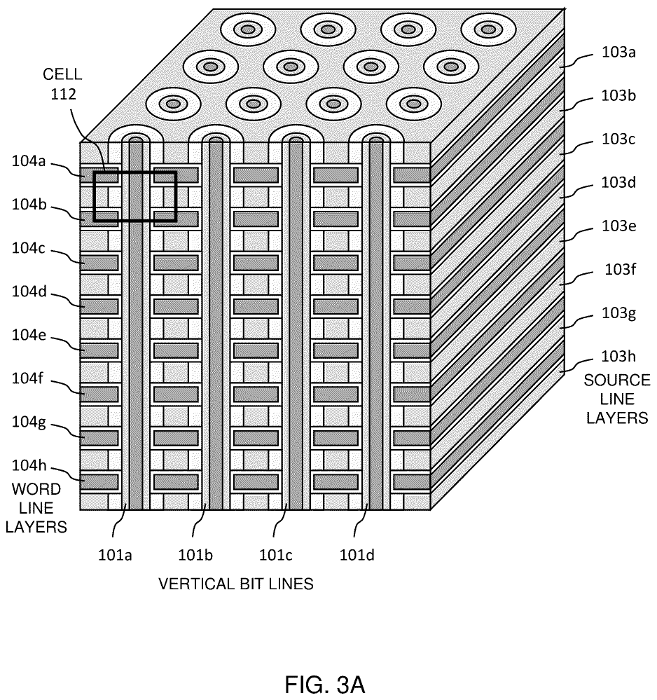

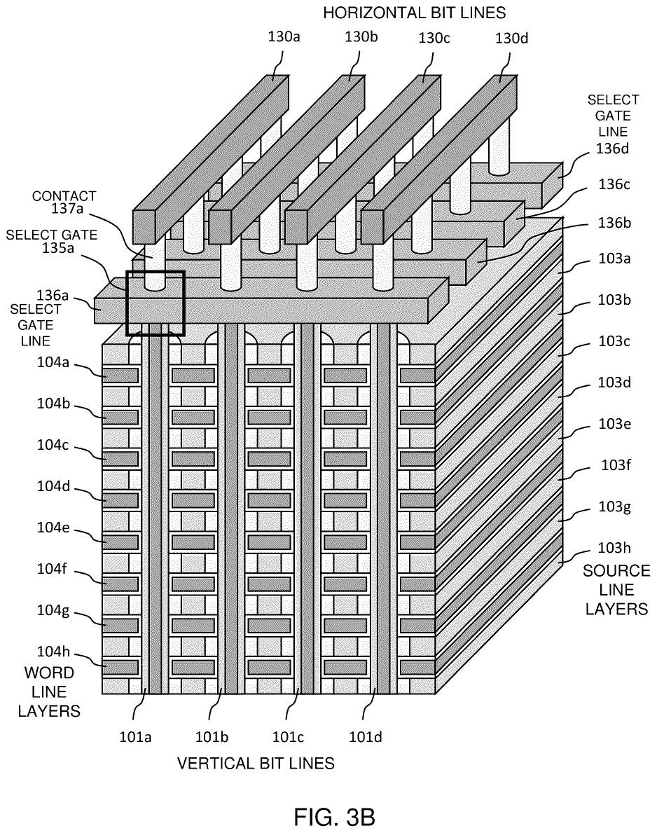

FIGS. 3A-B show embodiments of a 3D array structure constructed according to the invention. FIG. 3A shows a 3D array formed using the cell structures shown in FIGS. 1C-D. However, in other embodiments, the 3D array structure is formed utilizing any other cell structures shown in FIGS. 1A-2D. The 3D array comprises multiple layers of cells stacked vertically. The cells are connected to vertical bit lines, such as vertical bit lines 101a to 101d. The 3D array comprises multiple word line layers 104 a to 104 h that are connected to the gates of the cells. The 3D array also comprises multiple source line layers 103 a to 103h. Each intersection of one of the vertical bit lines 101a to 101d and one of the source lines 103a to 103h form a cell, such as the cell 112.

FIG. 3B shows an embodiment of a bit line connections to the 3D array structure shown in FIG. 3A that are constructed according to the invention. The vertical bit lines 101a to 101d are connected to horizontal bit lines 130a to 130d through select gates, such as select gate 135a and contacts, such as contact 137a. The horizontal bit lines 130a to 130d are formed of conductor material, such as metal or heavily doped polysilicon. The select gates, such as select gate 135a, are formed of vertical-channel transistors. Select gate lines 136a to 136d are connected to control gates of the vertical channel select gates, such as select gate 135a.

The word line layers 104a to 104h and source line layers 103a to 103h are connected to the word line decoders (not shown) and source line voltage generators (not shown), respectively, by forming staircase structures for the word lines and the source lines at the edge of the array as is structured in a conventional 3D NAND flash memory.

The 3D array structure can be utilized in various 3D NOR-type memory applications, such as dynamic random-access memory (DRAM) using floating-body cell (FBC), NOR-type flash memory, ferroelectric random-access memory (FRAM), resistive random-access memory (RRAM), phase change memory (PCM), and magnetoresistive random-access memory (MRAM).

Moreover, the 3D array structure can be applied to in-memory computing and 3D neural network arrays for artificial intelligence (AI) applications. For these applications, the vertical bit line 101a to 101d, word line layers 104a to 104h, and the source line layers 103a to 103h are connected to input neuron circuits and output neuron circuits. Besides these applications, the novel 3D cell and array structures constructed according to the invention are suitable for use in any other applications.

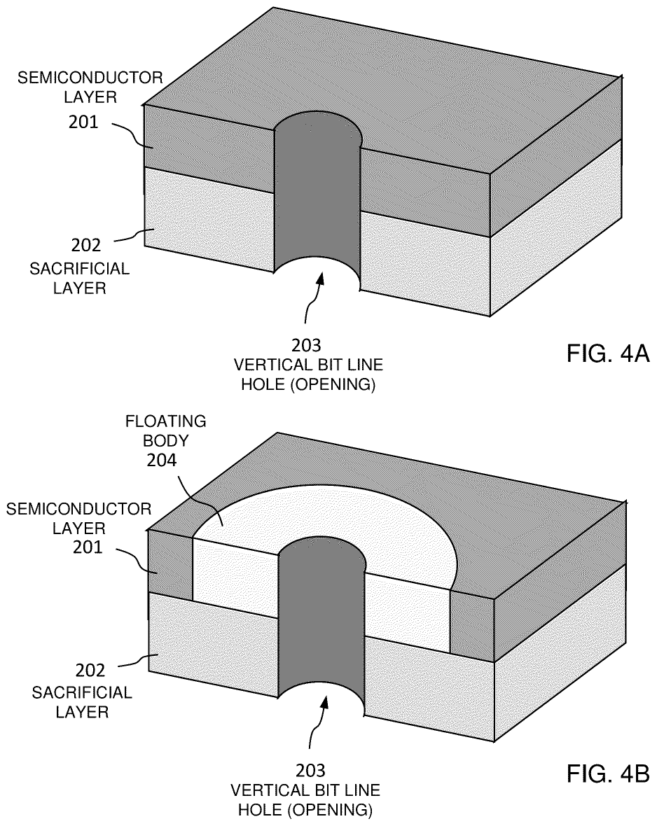

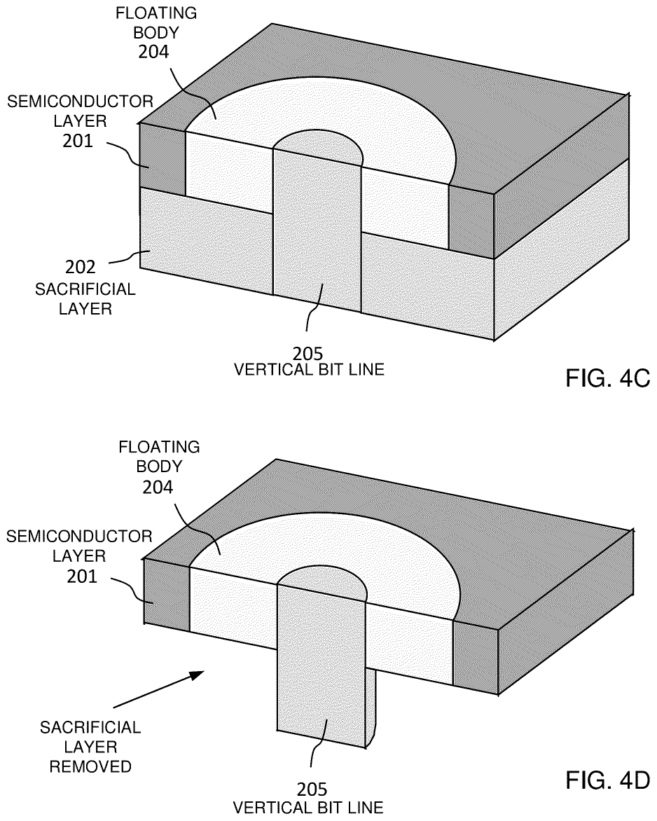

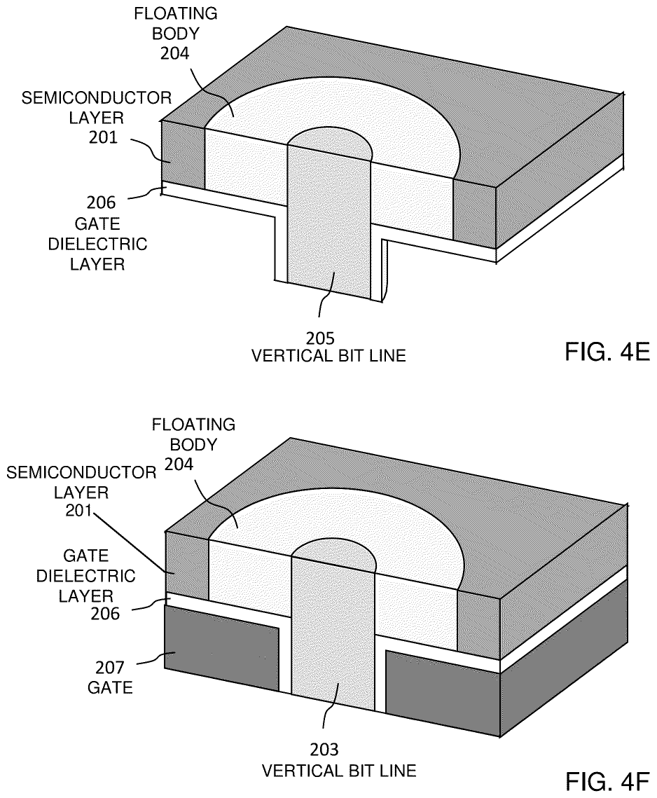

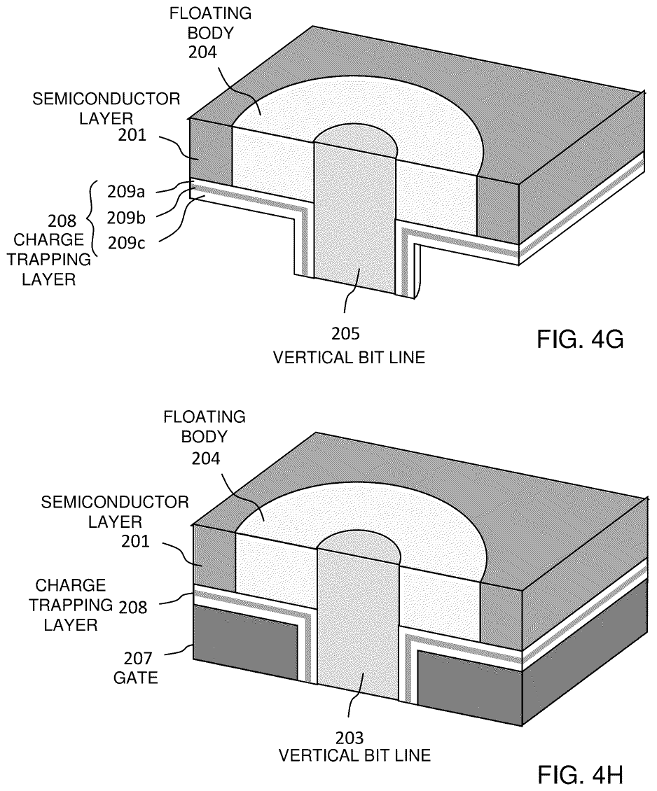

FIGS. 4A-F show embodiments of brief process steps used to form the floating-body cell structure shown in FIGS. 1A-B according to the invention.

FIG. 4A shows how multiple semiconductor layers 201, such as polysilicon or silicon and multiple sacrificial (or insulating) layers 202, such as oxide or nitride are alternately deposited to form a stack. For illustration, FIG. 4A only shows one semiconductor layer 201 and one sacrificial layer 202 but any number of semiconductor layers 201 and sacrificial layers 202 can be alternately deposited to form the stack.

In one embodiment, the semiconductor layers 201 are formed of amorphous silicon by using atomic layer deposition (ALD), plasma-enhanced atomic layer deposition (PE-ALD), or any other suitable deposition processes, such as chemical vapor deposition (CVD), physical vapor deposition (PVD), low pressure chemical vapor deposition (LPCVD), plasma-enhanced chemical vapor deposition (PECVD), or any other suitable process.

After deposition, an annealing process is applied to transfer the amorphous silicon into polycrystalline silicon (polysilicon). In one embodiment, the annealing process uses low-temperature rapid thermal annealing, such as 4 minutes at 700 degrees Celsius. It should be noted that any other suitable annealing process can be utilized.

The semiconductor layers 201 are doped by using an in-situ doping process during the deposition. For NMOS cells, N-type dopants, such as phosphine (PH3) or arsine (AsH3), are added during the deposition. For PMOS cells, P-type dopants, such as diborane (B2H6) are added during the deposition.

In another embodiment, the semiconductor layers 201 are formed using a polysilicon deposition process, such as high thermal decomposition of silane (SiH4) at 580 to 650 degrees Celsius. This process forms the polysilicon layers on the surface of the insulating layers 202 and releases hydrogen (H2).

In another embodiment, the semiconductor layers 201 are formed by using a silicon epitaxial growth process to form single-crystalline silicon (mono-silicon) on the surface of the sacrificial layers 202. However, this process may take a longer process time because the silicon layers need to be grown layer by layer.

The sacrificial layers 202 are formed by using deposition processes, such as atomic layer deposition (ALD), plasma-enhanced atomic layer deposition (PE-ALD), or any other suitable deposition processes, such as chemical vapor deposition (CVD), physical vapor deposition (PVD), low pressure chemical vapor deposition (LPCVD), plasma-enhanced chemical vapor deposition (PECVD), or any other suitable process.

After the multiple-layer stack is formed, multiple vertical bit line holes (or openings) 203 are formed by using photolithography steps to define a pattern, and then using anisotropic etching processes, such as deep trench process or dry etch process to etch through the multiple semiconductor layers 201 and the sacrificial layers 202 of the stack to form the vertical bit line hole 203.

FIG. 4B shows how a floating body 204 is formed in the semiconductor layer 201 by using gas-phase doping or collisional plasma doping (PLAD) or plasma immersion ion implantation (PIII), or any other suitable doping processes. For NMOS cells, diborane and hydrogen (B2H6/H2) plasma are used to implant boron ions through the vertical bit line holes 203 into the N-type semiconductor layers 201 to reverse the doping to form a P-floating body 204. For PMOS cells, phosphine (PH3) or Arsine (AsH3) plasma is used to implant phosphorus or Arsenic ions into the P-type semiconductor layers 201 to reverse the doping to form a N-floating body 204.

FIG. 4C shows how the vertical bit line holes 203 (e.g., shown in FIG. 4B) are filled with semiconductor material, such as heavily doped polysilicon to form a vertical bit lines 205. The semiconductor may be deposited by using any suitable deposition processes, such as atomic layer deposition (ALD), plasma-enhanced atomic layer deposition (PE-ALD), chemical vapor deposition (CVD), physical vapor deposition (PVD), low pressure chemical vapor deposition (LPCVD), plasma-enhanced chemical vapor deposition (PECVD), or any other suitable process. The semiconductor of the bit lines 205 is doped with the same type of heavy doping used for the semiconductor layers 201 by using an in-situ doping process. For NMOS cells, N-type dopants, such as phosphine (PH3) or arsine (AsH3) are added during the deposition of the vertical bit line 205. For PMOS cells, P-type dopants, such as diborane (B2H6) are added during the deposition of the vertical bit line 205.

FIG. 4D shows how the sacrificial layers 202 are selectively removed by using an isotropic etching process, such as wet etching. If the sacrificial layers 202 are oxide layers (SiO2), they can be etched by using buffered hydrofluoric acid (HF), ammonium fluoride (NH4F) or a mixture of hydrofluoric acid (HF) and nitric acid (HNO3). If the sacrificial layers 202 are nitride layers (Si3N4), they can be etched by using concentrated hot orthophosphoric acid (H3PO 4) at a temperature of 150 to 180 degrees Celsius.

FIG. 4E shows how a gate dielectric layer 206, comprising a gate oxide (SiO2) layer or a high-K material layer, such as hafnium oxide (HfO2), zirconium oxide (ZrO2), or titanium oxide (TiO2) is formed on the exposed surfaces of the semiconductor layer 201, floating body 204, and around the vertical bit line 205 that were previously covered by the sacrificial layer 202. The gate dielectric layer 206 is formed by using thermal oxidation or dry oxidation to grow a silicon oxide (SiO2) layer on the exposed surfaces of the semiconductor layers 201, the floating body 204, and around the vertical bit lines 205, or by using atomic layer deposition (ALD), plasma-enhanced atomic layer deposition (PE-ALD), or any other suitable deposition processes to deposit a thin layer of the gate dielectric material on the exposed surfaces of the semiconductor layers 201, the floating body 204, and around the vertical bit lines 205.

FIG. 4F shows how the spaces (or regions) that were previously occupied by the sacrificial layers 202 are filled with metal, such as tungsten (W), tantalum (Ta), titanium (Ti), niobium (Nb) for NMOS cells, or ruthenium (Ru) for PMOS cells, or the composite of metal nitride such as WN, TaN, and TiN, or heavily doped polysilicon to form gates 207 of the cell transistors. The gates 207 are formed by using deposition processes, such as atomic layer deposition (ALD), plasma-enhanced atomic layer deposition (PE-ALD), chemical vapor deposition (CVD), physical vapor deposition (PVD), low pressure chemical vapor deposition (LPCVD), plasma-enhanced chemical vapor deposition (PECVD), or any other suitable processes. As a result of the above operations, the floating-body cell structure shown in FIGS. 1A-B is formed.

FIGS. 4G-H show another embodiment of brief process steps used to form the cell structure of the 3D NOR-type flash memory shown in FIGS. 2A-B. In this embodiment, FIG. 4G shows a process step that is performed after the process step shown in FIG. 4D. In FIG. 4G, a charge-trapping layer 208, such as oxide-nitride-oxide (ONO) layer, which comprises a tunnel oxide layer 209a, a nitride layer 209b, and a blocking oxide layer 209c is formed in the region previously occupied by the sacrificial layers 202 on the exposed surfaces of the semiconductor layers 201, the floating body 204, and around the vertical bit lines 205. The charge-trapping layer 208 is formed by using atomic layer deposition (ALD), plasma-enhanced atomic layer deposition (PE-ALD), or any other suitable deposition processes to deposit the ONO layers one by one.

FIG. 4H shows how the spaces (or regions) that were previously occupied by the sacrificial layers 202 are filled with the gate materials described in FIG. 4F, such as metal or heavily doped polysilicon to form the gate 207. As a result of the above operations, the NOR-type flash memory cell structure shown in FIGS. 2A-B is formed.

In another embodiment, the process steps shown in FIGS. 4G-H are applied to form the cell embodiments of FRAM, RRAM, MRAM, or PCM as shown in FIGS. 2C-D by using different materials and structures for the non-volatile memory gate dielectric layers 170a/170b as a replacement for the charge-trapping layer 208. FIGS. 2C-D provide detailed descriptions for forming the non-volatile memory gate dielectric layers 170a and 170b.

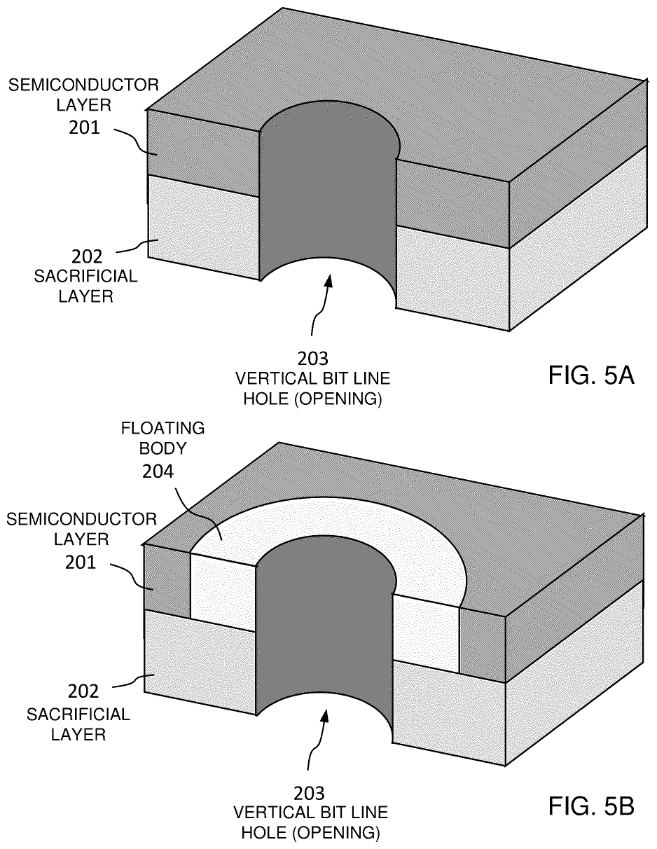

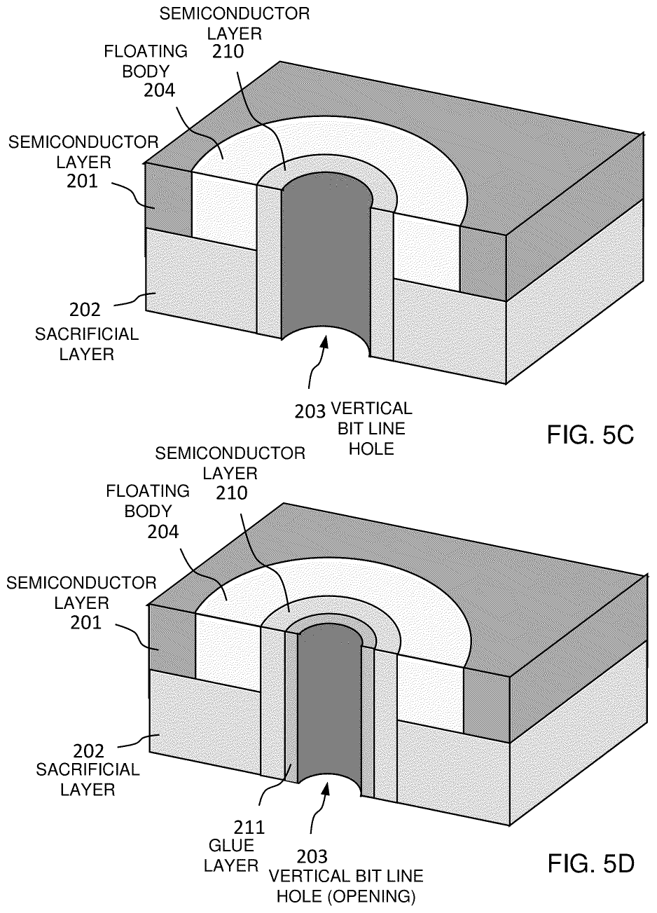

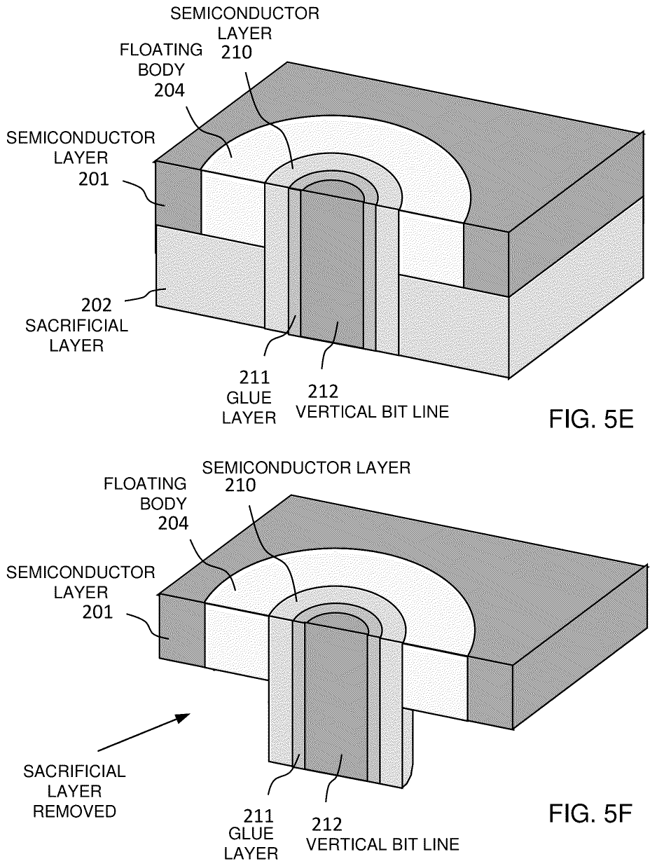

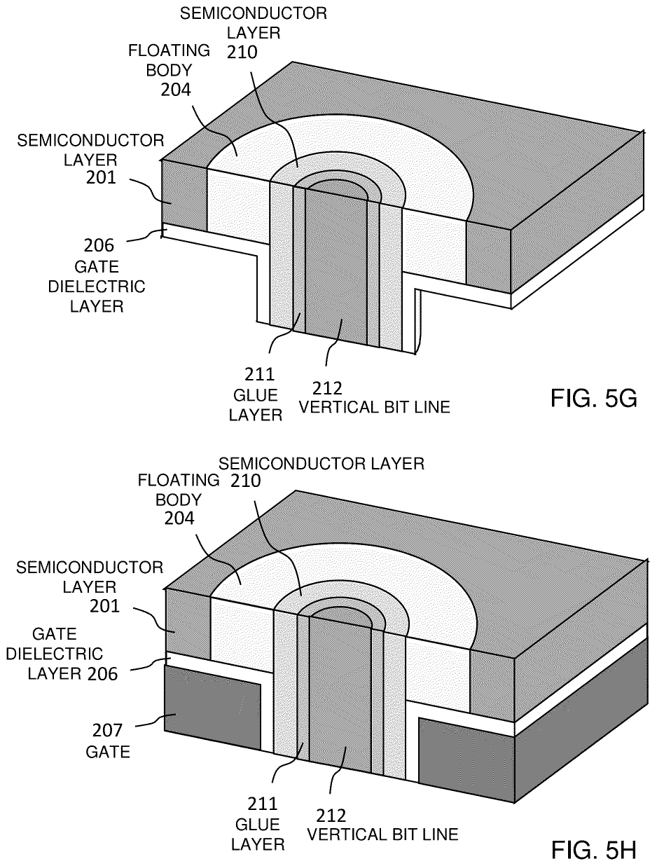

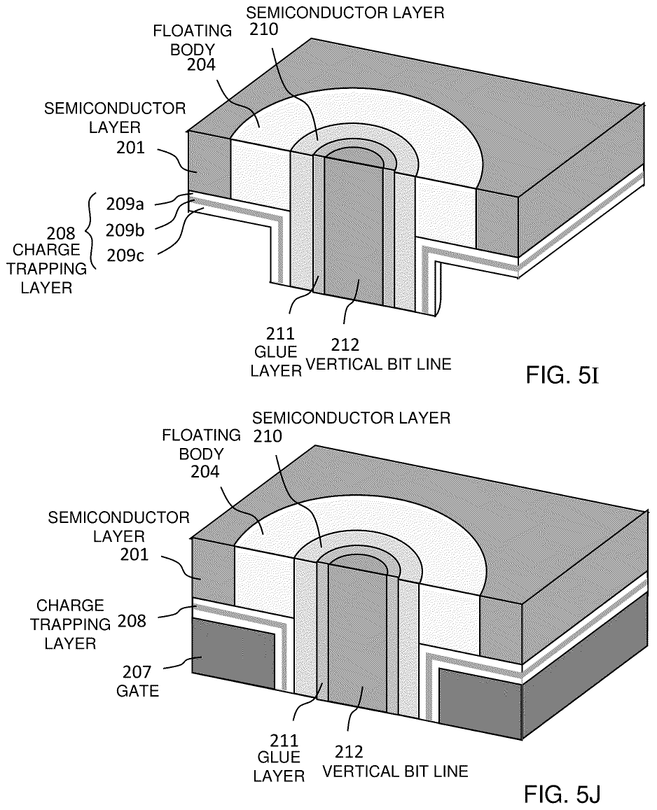

FIGS. 5A-H show embodiments of brief process steps to form the floating-body cell structure shown in FIGS. 1C-D according to the invention.

FIG. 5A shows how multiple semiconductor layers 201, such as polysilicon or silicon and multiple sacrificial layers 202, such as oxide or nitride are alternately deposited to form a stack. After that, multiple vertical bit line holes 203 are patterned by using lithography steps and using an anisotropic etching process, such as deep trench to etch through the multiple layers of the stack to form a vertical bit line hole (or opening) 203.

FIG. 5B shows how a plasma doping (PLAD) or gas-phase doping process is applied through the vertical bit line holes 203 to dope the semiconductor layers 201 with the opposite type of dopants as used in the semiconductor layers 201 to form a floating body 204. For example, if the semiconductor layers 201 has N-type of dopants, such as phosphorus, the plasma doping process uses P-type of dopants, such as boron to form a P-type floating body 204. The process steps shown in FIGS. 5A-B are as the same as those shown in FIGS. 4A-B. The reader is referred to FIGS. 4A-B for a detailed description.

FIG. 5C shows how a semiconductor layer 210, such as polysilicon or silicon is formed on the sidewall of the vertical bit line holes 203 by using the deposition processes described in FIG. 4A, such as atomic layer deposition (ALD), plasma-enhanced atomic layer deposition (PE-ALD), or any other suitable deposition processes, or using epitaxial growth processes to grow a single-crystalline silicon layer. The semiconductor layer 210 is then doped with the same type of heavy doping as the semiconductor layers 201 by using an in-situ doping process. For NMOS cells, N-type dopants, such as phosphine (PH3) or arsine (AsH3) are added during the deposition of the semiconductor layer 210. For PMOS cells, P-type dopants, such as diborane (B2H6) are added during the deposition of the semiconductor layer 210.

FIG. 5D shows how a glue layer 211, such as titanium and titanium nitride (Ti/TiN) layer is formed on the sidewall of the semiconductor layer 210 to prevent peeling of metal bit lines that are added in a future step and thus improve the reliability. The TiN and Ti layers are formed by using chemical vapor deposition (CVD) and an ion metal plasma (IMP) physical vapor deposition (PVD) process, respectively. As a result of the operations performed with respect to FIGS. 5C-D, the size of the vertical bit line hole 203 is reduced by the thickness of the semiconductor layer 210 and the glue layer 211. It should be noted that in this embodiment and other embodiments within this disclosure, the use of a glue layer, such as glue layer 211 is optional, and if desired, can be omitted.

FIG. 5E shows how the vertical bit line holes 203 (that are reduced in size due to the layers 210 and 211) are filled with high melting point metal, such as tungsten (W) to form vertical bit lines 212. The tungsten is deposited by using any suitable deposition processes, such as chemical vapor deposition (CVD) reaction with tungsten hexafluoride (WF6) plus hydrogen (H2) and silane (SiH4). The metal bit lines 212 provide reduced bit line resistance compared with other embodiments that use semiconductor bit lines, such as bit line 205 shown in FIG. 4C.

FIG. 5F shows how the sacrificial layers 202 are selectively removed by using an isotropic etching process, such as wet etching.

FIG. 5G shows how a gate dielectric layer 206 comprising a gate oxide (SiO2) layer or a high-K material layer, such as hafnium oxide (HfO2), zirconium oxide (ZrO2), or titanium oxide (TiO2) is formed on the exposed surfaces of the semiconductor layer 201, floating body 204, and around the semiconductor layer 210 that were previously covered by the sacrificial layer 202.

FIG. 5H shows how the spaces (or regions) that were previously occupied by the sacrificial layers 202 are filled with metal, such as tungsten (W), tantalum (Ta), titanium (Ti), niobium (Nb) for NMOS cells, or ruthenium (Ru) for PMOS cells, or the composite of metal nitride such as WN, TaN, and TiN, or heavily doped polysilicon to form gates 207 of the cell transistors. The process steps shown in FIGS. 5F-H are the same as the step shown in FIGS. 4D-F. The reader is referred to FIGS. 4D-F for a detailed description. As a result of the above operations, the floating-body cell structure shown in FIGS. 1C-D is formed.

FIGS. 5I-J show another embodiment of brief process steps used to form the cell structure of a 3D NOR-type flash memory.

FIG. 5I shows a process step that is performed after the process step shown in FIG. 5F. FIG. 5I shows how a charge-trapping layer 208, such as an oxide-nitride-oxide (ONO) layer, which comprises a tunnel oxide layer 209a, a nitride layer 209b, and a blocking oxide layer 209c is formed in the region previously occupied by the sacrificial layers 202 on the exposed surfaces of the semiconductor layers 201, the floating body 204, and around the semiconductor layer 210. The charge-trapping layer 208 is formed by using atomic layer deposition (ALD), plasma-enhanced atomic layer deposition (PE-ALD), or any other suitable deposition processes to deposit the ONO layers one by one. An exemplary process and description are provided with reference to FIG. 4G.

FIG. 5J shows how the spaces (or regions) that were previously occupied by the sacrificial layers 202 are filled with the gate materials described in FIG. 4F, such as metal or heavily doped polysilicon to form the gate 207. As a result, a NOR-type flash memory cell structure is formed.

In another embodiment, the process steps shown in FIGS. 5I-J are applied to form the cell embodiments of FRAM, RRAM, MRAM, or PCM as shown in FIGS. 2C-D by using different materials and structures for a non-volatile memory gate dielectric layer to replace the charge-trapping layer 208. The reader is referred to FIGS. 2C-D for a detailed description of the non-volatile memory gate dielectric layers 170a and 170b.

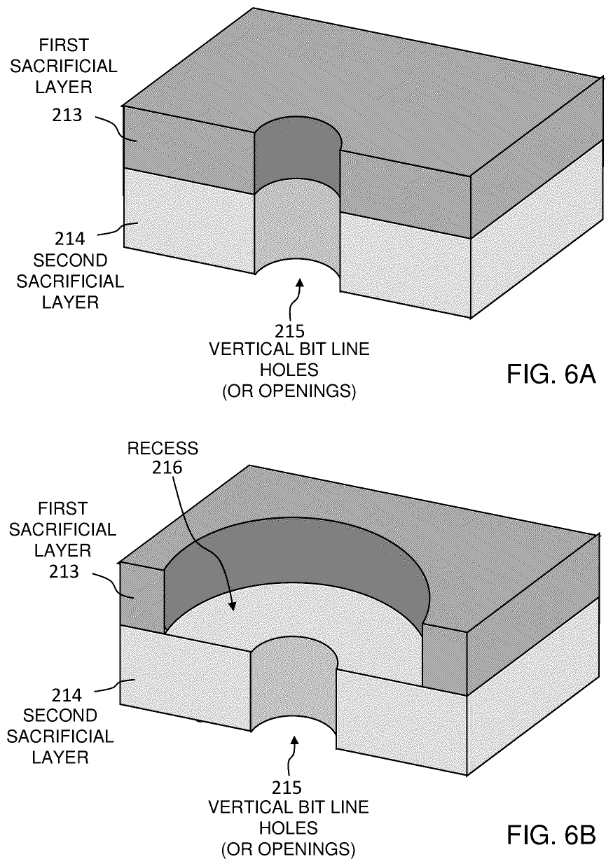

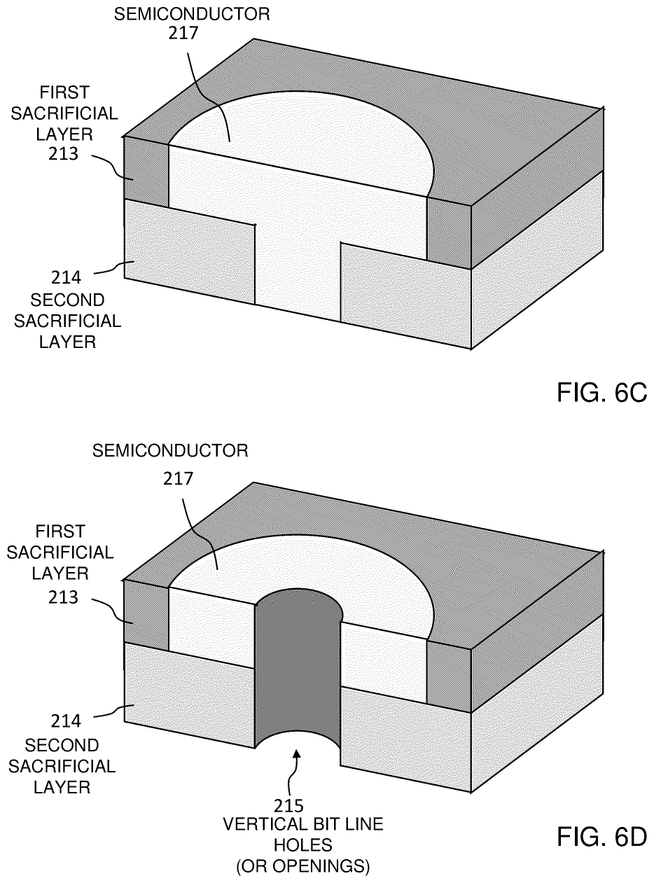

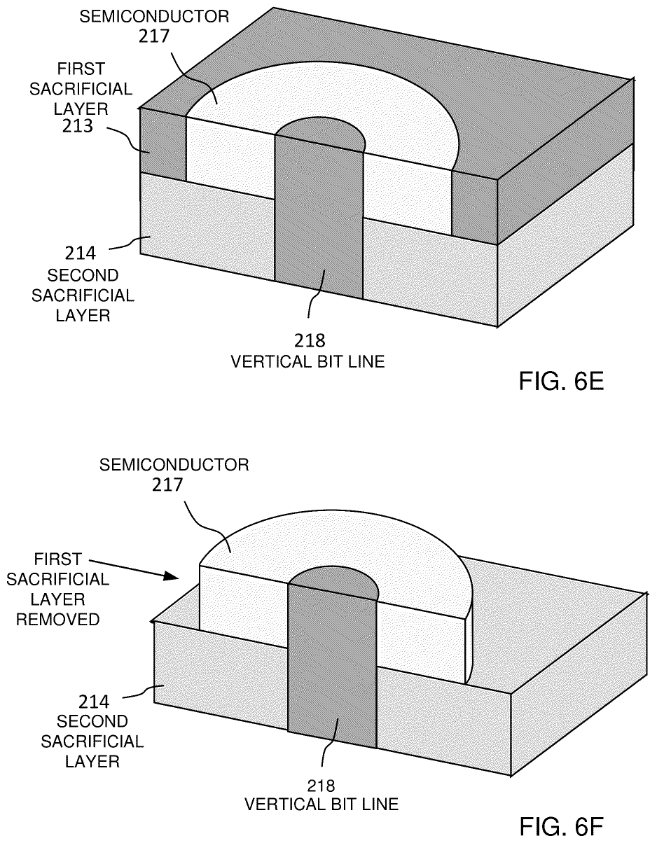

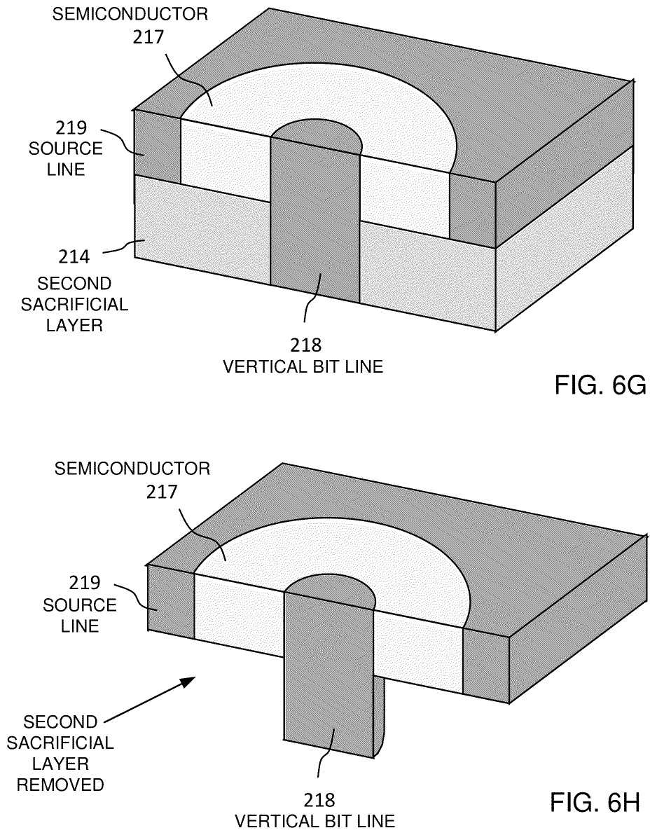

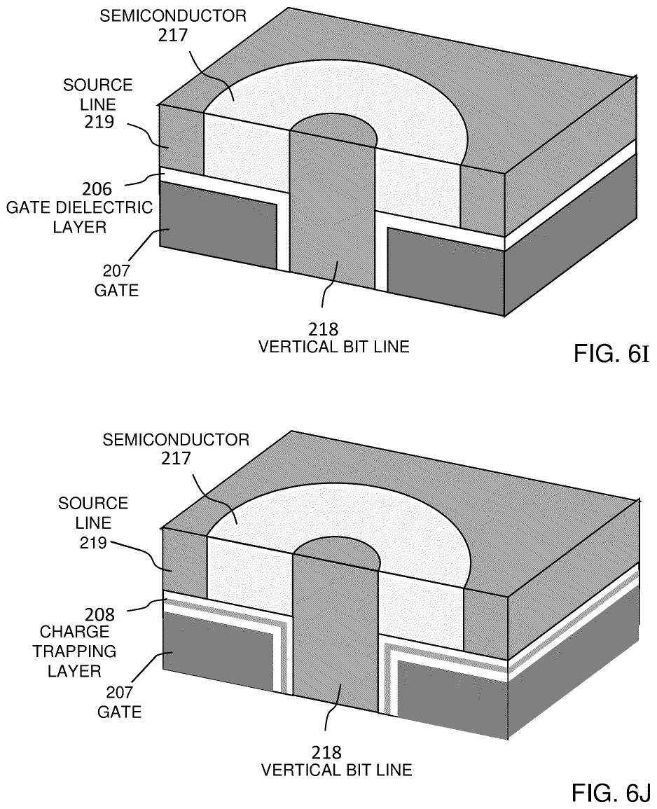

FIGS. 6A-B show another embodiment of brief process steps to form the junction-less floating-body cell structure shown in FIGS. 1I-J according to the invention.

FIG. 6A shows how multiple first sacrificial layers 213 and multiple second sacrificial layers 214 are alternately deposited to form a stack. For illustration, FIG. 6A only shows one first sacrificial layer 213 and one second sacrificial layer 214. However, a plurality of the first 213 and second 214 sacrificial layers can be alternately deposited to form the stack. The materials of the first 213 and second 214 sacrificial layers have different etching selectivity. For example, in one embodiment, the first sacrificial layer 213 is an oxide (SiO2) and the second sacrificial layer 214 is a nitride (Si3N4). After the stack is formed, multiple vertical bit line holes 215 (or openings) are formed by using photolithography steps to define a pattern, and then using an anisotropic etching process, such as deep trench etching or dry etching to etch through the multiple first sacrificial layers 213 and second sacrificial layers 214 of the stack to form the vertical bit line holes (or openings) 215.

FIG. 6B shows how an isotropic etching process, such as wet etching is performed through the vertical bit line holes 215 to selectively etch the first sacrificial layer 213 to form a recess (or opening) 216 in the first sacrificial layer 213. When the first sacrificial layers 213 are formed of silicon oxide (SiO2), etching is performed using buffered hydrofluoric acid (HF) with ammonium fluoride (NH4F) or a mixture of hydrofluoric acid (HF) and nitric acid (HNO3).

FIG. 6C shows how the recess 216 and the vertical bit line holes 215 are filled with semiconductor 217, such as polysilicon or silicon. In one embodiment, the polysilicon is formed by using the polysilicon deposition processes or the silicon epitaxial growth process described with reference to FIG. 4A. The reader is referred to the description of FIG. 4A for a detailed description. The semiconductor 217 is doped by using an in-situ doping process. For NMOS cells, N-type dopants, such as phosphine (PH3) or arsine (AsH3) are added during the deposition of the semiconductor 217. For PMOS cells, P-type dopants, such as diborane (B2H6) is added during the deposition process of the semiconductor 217.

FIG. 6D shows how an anisotropic etching process, such as dry etching is performed using the second sacrificial layers 214 as a hard mask to selectively etch the semiconductor 217 to re-form the vertical bit line holes 215. Because this etching process is self-aligned using the second sacrificial layers 214 as a hard mask, the etching process achieves a high process yield. After the vertical bit line holes 215 are re-formed, the semiconductor 217 within the recess becomes the channel region of the cell transistor. In one embodiment, the re-formed bit line hole 215 is the same dimension as shown in FIG. 6A.

FIG. 6E shows how the vertical bit line holes 215 are filled with a high melting point metal, such as tungsten (W) to form the vertical bit lines 218. The tungsten is deposited by using any suitable deposition processes, such as a chemical vapor deposition (CVD) reaction with tungsten hexafluoride (WF6) plus hydrogen (H2) and silane (SiH4).

FIG. 6F shows how the first sacrificial layers 213 are selectively removed by using an isotropic etching process, such as wet etching. If the first sacrificial layers 213 are formed of silicon oxide (SiO2), they are etched by using buffered hydrofluoric acid (HF) with ammonium fluoride (NH4F) or a mixture of hydrofluoric acid (HF) and nitric acid (HNO3).

FIG. 6G shows how a high melting point metal, such as tungsten (W) is deposited to fill the spaces that are previously occupied by the first sacrificial layers 213 to form the source line layer 219. The tungsten is deposited using any suitable deposition processes, such as a chemical vapor deposition (CVD) reaction with tungsten hexafluoride (WF6) plus hydrogen (H2) and silane (SiH4).

FIG. 6H shows how the second sacrificial layers 214 are selectively removed by using an isotropic etching process, such as wet etching. If the second sacrificial layers 214 are formed of silicon nitride (Si3N4), they are etched by using concentrated hot orthophosphoric acid (H3PO 4) at a temperature of 150 to 180 degrees Celsius.

FIG. 6I shows how the process steps described with reference to FIGS. 4E-F are performed to form the gate dielectric layer 206 and the gates 207. The reader is referred to the description of FIGS. 4E-F for a detailed description of the process steps. As a result, a floating-body cell structure using a junction-less transistor is formed as illustrated in FIG. 6I.

FIG. 6J shows another embodiment for forming a junction-less transistor. After the process step shown in FIG. 6H, the process steps shown in FIGS. 4G-H are performed to form the charge-trapping layer 208 and the gates 207. The reader is referred to the description of FIGS. 4G-H for a detailed description of these steps. As a result, a NOR-type flash memory cell structure using a junction-less transistor is formed as illustrated in FIG. 6J.

In another embodiment, the charge-trapping layer 208 shown in FIG. 6J is replaced with a non-volatile memory gate dielectric layer formed from the materials described with reference to FIGS. 2C-D to form the cell embodiments of FRAM, RRAM, MRAM, or PCM. The reader is referred to the description of FIGS. 2C-D for the detailed descriptions of the non-volatile memory gate dielectric layers 170a and 170b.

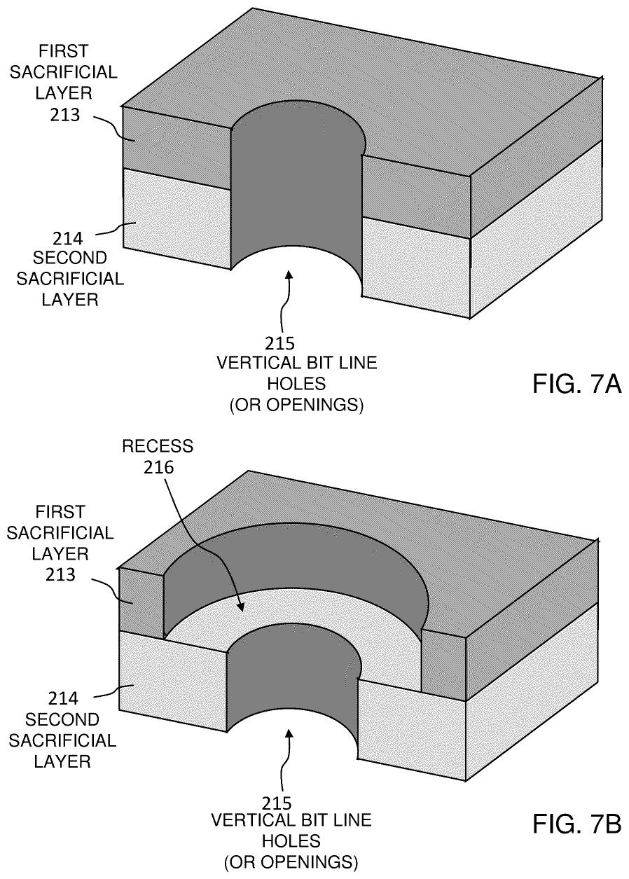

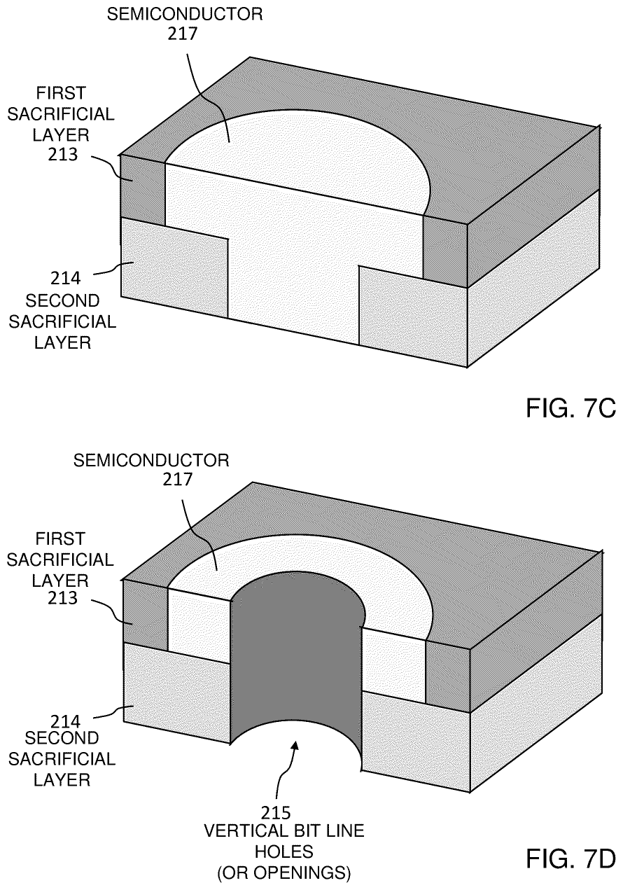

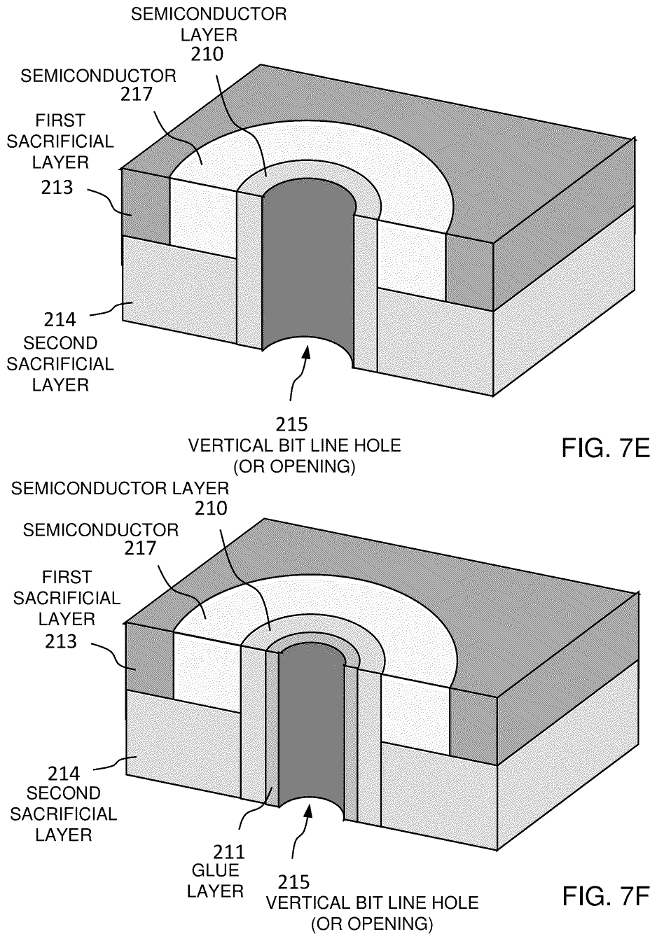

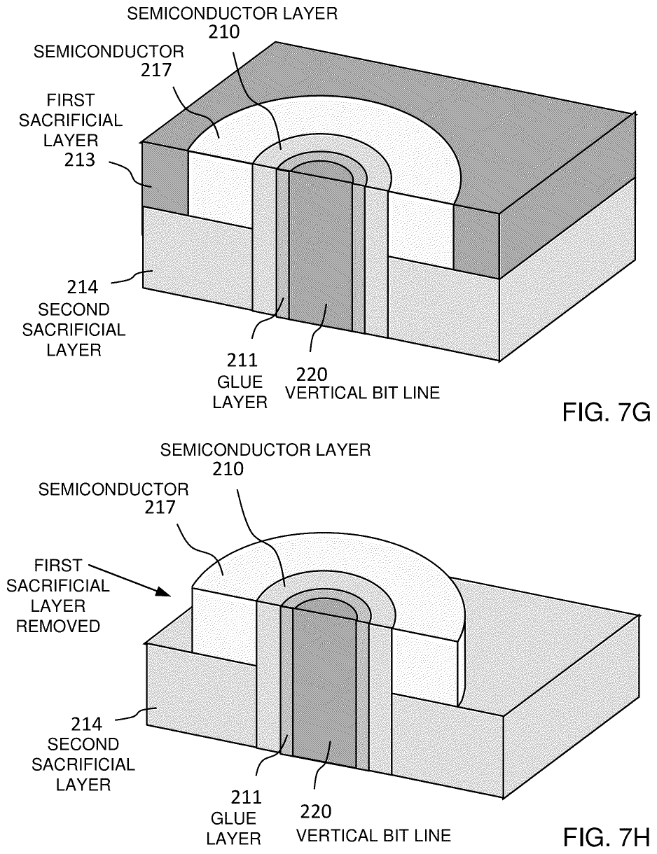

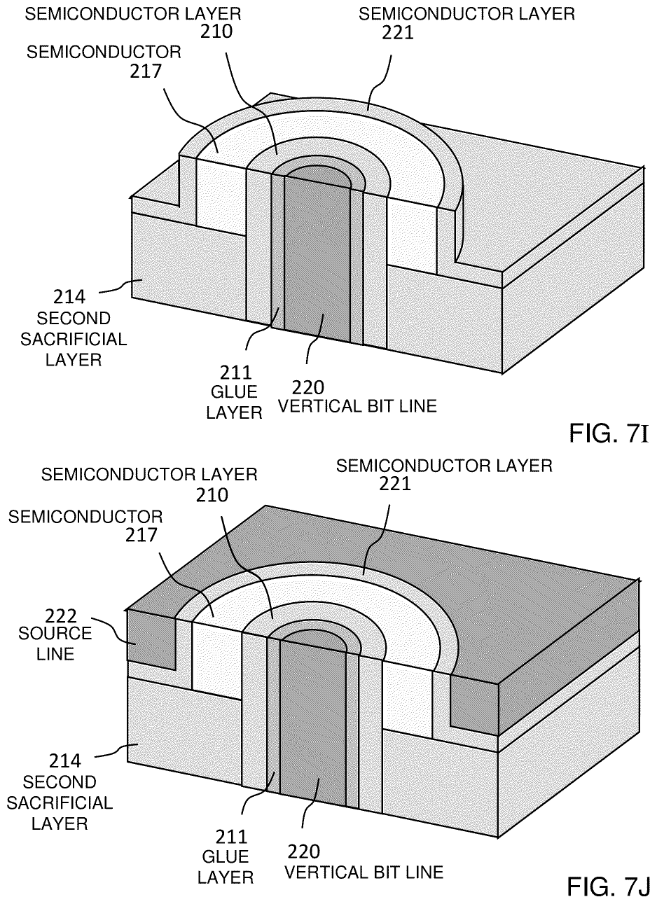

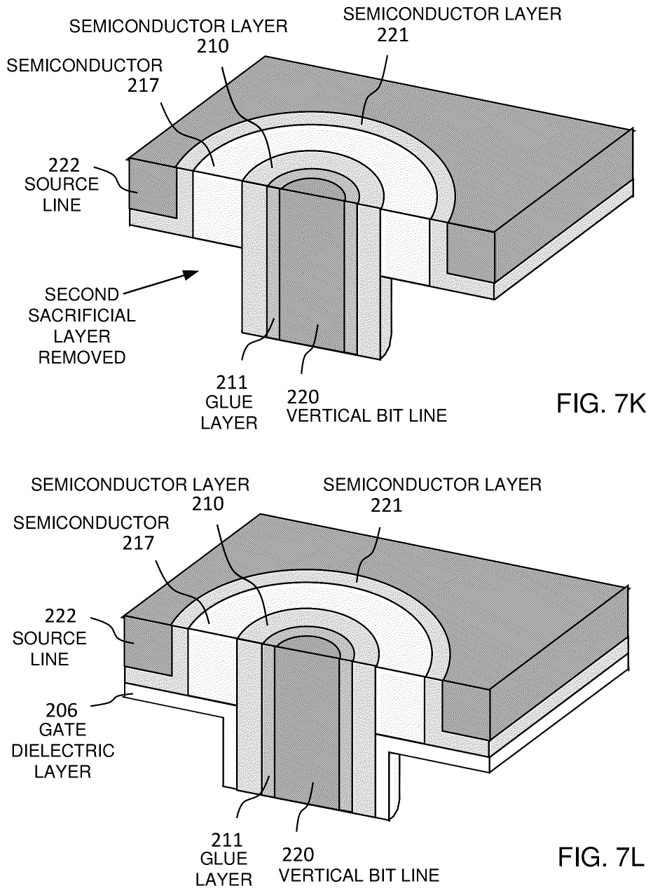

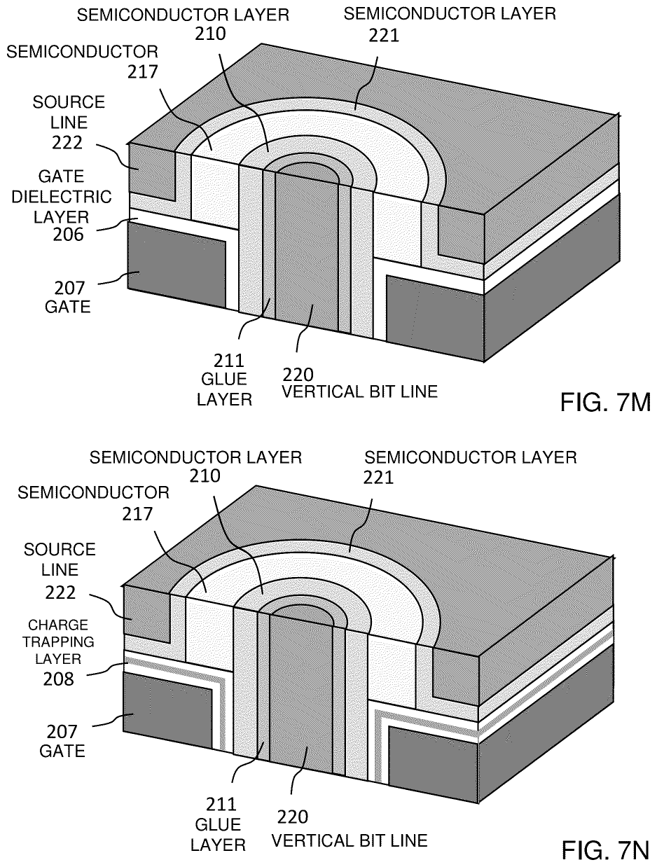

FIGS. 7A-M show another embodiment of brief process steps to form the cell structure shown in FIGS. 1G-H according to the invention.

FIG. 7A shows how multiple first sacrificial layers 213, such as oxide (SiO2) and multiple second sacrificial layers 214, such as nitride (Si3N4) are alternately deposited to form a stack. After that, multiple vertical bit line holes 215 are patterned by using photolithography steps and formed by using an anisotropic etching process, such as deep trench etching to etch through the multiple layers of the stack. In an embodiment, a plurality of first sacrificial layers 213 and a plurality of second sacrificial layers are alternately deposited to form the stack.

FIG. 7B shows how a recess 216 is formed by using an isotropic etching process, such as wet etching to etch through the vertical bit line holes 215 to selectively etch the first sacrificial layers 213 so that the recess 216 is formed.

FIG. 7C shows how the recess 216 and the vertical bit line hole 215 are filled with semiconductor 217 such as polysilicon or silicon. The semiconductor layer 217 is doped by using an in-situ doping process.

FIG. 7D shows how an anisotropic etching process, such as dry etching is performed using the second sacrificial layers 214 as a hard mask to selectively etch the semiconductor 217 to re-form the vertical bit line hole 215. In one embodiment, the re-formed bit line hole 215 has the same dimension as shown in FIG. 7A. After the vertical bit line hole 215 is re-formed, the semiconductor 217 becomes a floating body of the cell. The process steps described with reference to FIGS. 7A-D are as the same as the process steps described with reference to FIGS. 6A-D. The reader is referred to the description of FIGS. 6A-D for a detailed description of those process steps.

FIG. 7E shows how a semiconductor layer 210, such as polysilicon or silicon is formed on the sidewall of the semiconductor 217 through the vertical bit line holes 215. The semiconductor layer 210 is doped with the opposite type of the doping that is used for the floating body 217.

FIG. 7F shows how a glue layer 211, such as a titanium and titanium nitride (Ti/TiN) layer is formed on the sidewall of the vertical bit line holes 215.

FIG. 7G shows how the vertical bit line holes 215 are filled with a high melting point metal, such as tungsten (W) by using deposition processes to form a vertical bit line 220. The process steps shown in FIGS. 7E-G are as the same as FIGS. 5C-E. The reader is referred to the description of FIGS. 5C-E for the detailed description of these process steps.

FIG. 7H shows how the first sacrificial layers 213 are selectively removed by using an isotropic etching process, such as wet etching. If the first sacrificial layers 213 are formed of silicon oxide (SiO2), they are etched by using buffered hydrofluoric acid (HF) with ammonium fluoride (NH4F) or a mixture of hydrofluoric acid (HF) and nitric acid (HNO3).

FIG. 7I shows how a semiconductor layer 221, such as polysilicon or silicon is formed on the exposed surfaces of the second sacrificial layer 214 and the semiconductor 217 in the space that was previously occupied by the first sacrificial layer 213. The semiconductor layer 221 is formed by the polysilicon deposition processes or silicon epitaxial growth process described with reference to FIG. 4A. The semiconductor layer 221 is doped using an in-situ doping process. For NMOS cells, N-type dopants, such as phosphine (PH3) or arsine (AsH3) are added during the deposition of the semiconductor layer 221. For PMOS cells, P-type dopants, such as diborane (B2H6) are added during the deposition of the semiconductor layer 221.

In another embodiment, the semiconductor layer 221 is formed by using a plasma doping (PLAD) process or any other suitable doping process to dope the opposite type of heavy dopants used for the floating body 217 into the semiconductor layer 221 so that the semiconductor layer 221 will have the reverse doping type as the floating body 217. For example, if the floating body 217 has P-type doping, the plasma doping process is used to dope N-type of heavy dopants (e.g., the opposite type of dopants of the floating body 217), such as phosphorus into the layer 221 to reverse the doping type of the layer 221 from P-type to N-type. This forms an N-type of semiconductor layer 221.

FIG. 7J shows how a high melting point metal, such as tungsten (W) or heavily doped polysilicon is deposited to fill the spaces that were previously occupied by the first sacrificial layers 213 to form the source line layer 222. The tungsten is deposited by using any suitable deposition processes, such as chemical vapor deposition (CVD) reaction with tungsten hexafluoride (WF6) plus hydrogen (H2) and silane (SiH4). Compared with other embodiments shown in FIG. 4A-F that form the silicon or polysilicon source lines 103, the metal source lines 222 reduce the source line resistance.

FIG. 7K shows how the second sacrificial layers 214 are selectively removed by using an isotropic etching process, such as wet etching.

FIG. 7L shows how a gate dielectric layer 206 is formed on the exposed surfaces of the semiconductor layer 221, semiconductor 217 and around the surface of the semiconductor layer 210 within the space previously occupied by the second sacrificial layer 214.

FIG. 7M shows how the spaces along the exposed surface of the gate dielectric layer 206 are filled with metal or heavily doped polysilicon to form the gates 207. The process steps shown and described with referenced to FIGS. 7K-M are as the same as those shown and described with reference to FIGS. 4D-F. The reader is referred to the description of FIGS. 4D-F for the detailed description of those process steps. As a result, the floating-body cell structure shown in FIGS. 1G-H is formed.

FIG. 7N shows another embodiment of process steps utilized to form a cell structure. After the process step shown and described with reference to FIG. 7K are performed, the process steps shown and described with reference to FIGS. 4G-H are performed to form a charge-trapping layer 208 and gates 207 shown in FIG. 7N. The reader is referred to the description of FIGS. 4G-H for the detailed description of those process steps. As a result, a NOR-type flash memory cell structure as shown in FIG. 7N is formed.

In another embodiment, the charge-trapping layer 208 shown in FIG. 7N is replaced with a non-volatile memory gate dielectric layer formed from the materials described with reference to FIGS. 2C-D to form the cell embodiments of FRAM, RRAM, MRAM, or PCM. The reader is referred to the description of FIGS. 2C-D for the detailed descriptions for forming the non-volatile memory gate dielectric layers 170a and 170b using these materials.

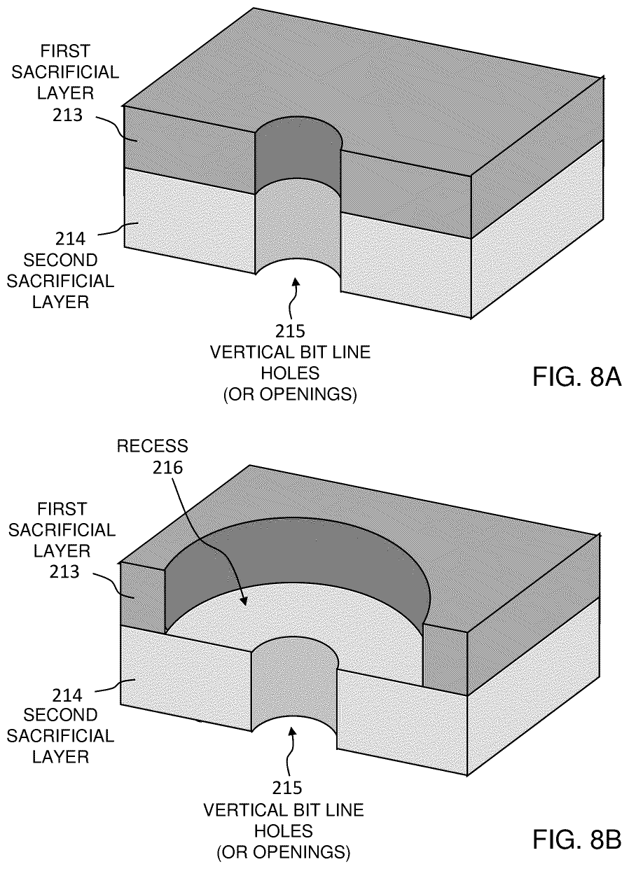

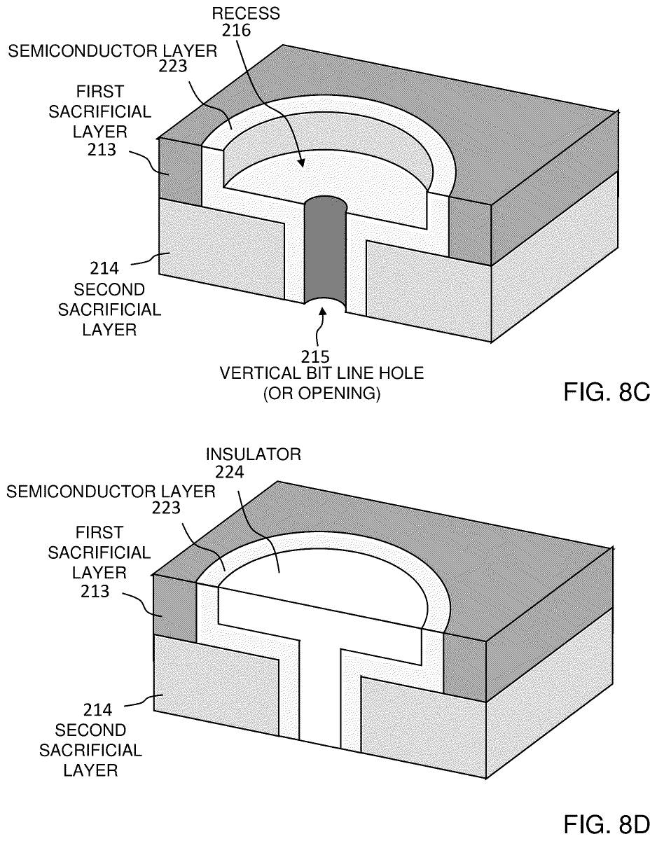

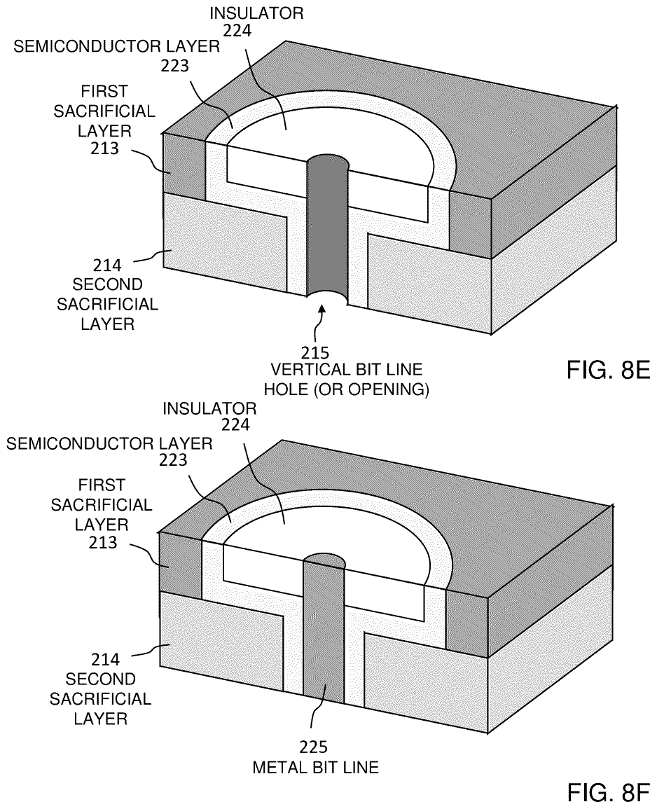

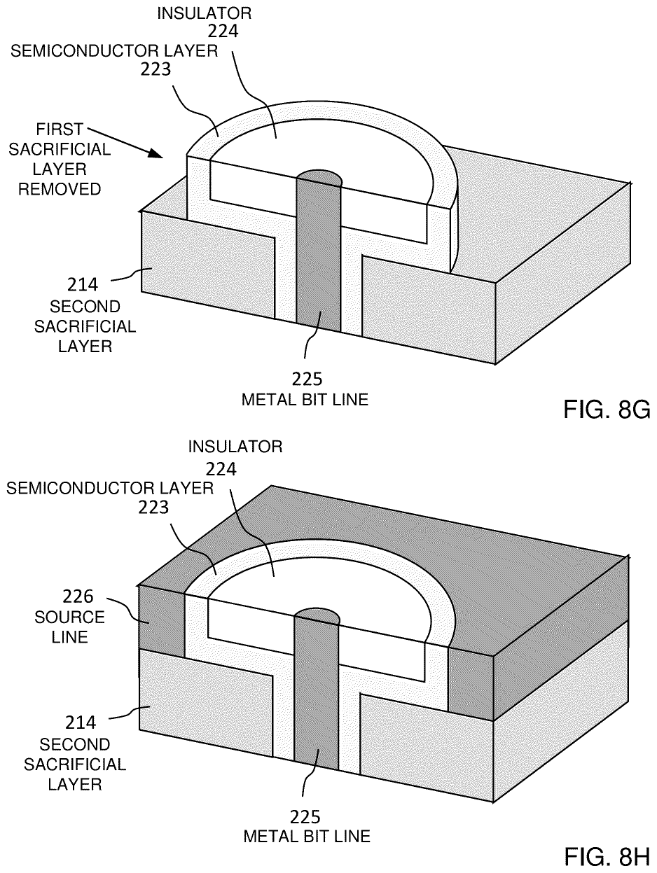

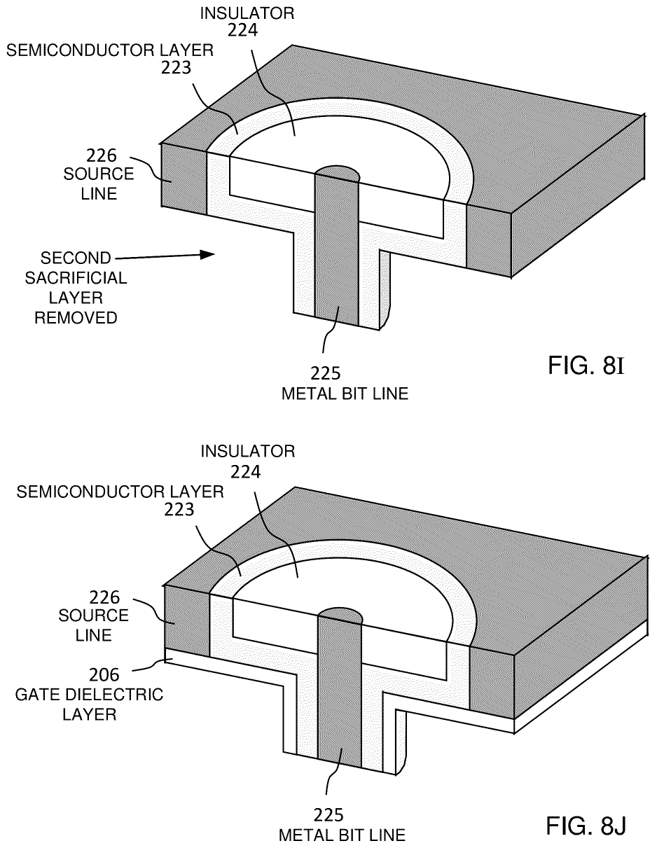

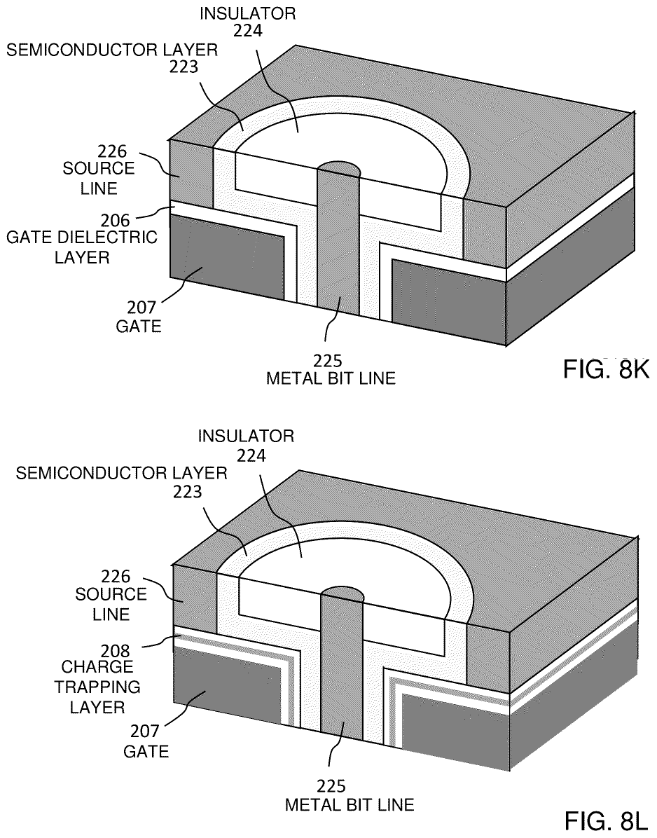

FIGS. 8A-K show another embodiment of brief process steps to form a cell structure comprising a thin-film transistor as shown in FIGS. 1K-L according to the invention.

FIG. 8A shows how multiple first sacrificial layers 213, such as oxide (SiO2) and multiple second sacrificial layers 214, such as nitride (Si3N4) are alternately deposited to form a stack. After that, multiple vertical bit line holes 215 are patterned by using photolithography steps and then formed by using an anisotropic etching process, such as deep trench etching to etch through the multiple layers of the stack. In an embodiment, the stack comprises a plurality of alternating layers.

FIG. 8B shows how recess 216 are formed by using an isotropic etching process, such as wet etching to selectively etch the first sacrificial layers 213 through the vertical bit line holes 215. The process steps shown and described with reference to FIGS. 8A-B are as the same as those shown and described with reference to FIGS. 6A-B. The reader is referred to the description of FIGS. 6A-B for the detailed description of those process steps.

FIG. 8C shows how a semiconductor layer 223, such as polysilicon or silicon is formed on the surface of the sidewall of the recess 216 and the vertical bit line holes 215. As a result, the size of the recess 216 and the vertical bit line hole 215 are reduced. The semiconductor layer 223 is formed by using the polysilicon deposition processes or the silicon epitaxial growth process through the bit line holes 215 as described with reference to FIG. 4A. The reader is referred to the description of FIG. 4A for the detailed description of the process to form the semiconductor layer 223.

FIG. 8D shows how the recess 216 and the vertical bit line holes 215 are filled with an insulator 224, such as oxide (SiO2) or nitride (Si3N4) by using a deposition process.

FIG. 8E shows how an anisotropic etching process, such as dry etch is performed using the second sacrificial layers 214 and the semiconductor layer 223 as hard masks to selectively etch the insulator 224 to re-form the vertical bit line hole (or opening) 215. It should be noted that the re-formed vertical bit line hole 215 shown in FIG. 8E has a smaller diameter than the vertical bit line hole 215 shown in FIG. 8A. The etching processes for oxide and nitride are described above in reference to FIG. 6B. The reader is referred to the description of FIG. 6B for the detailed description of the etching process for forming the bit line hole 215.

FIG. 8F shows how the vertical bit line hole 215 is filled with a high melting point metal, such as tungsten (W) by using deposition processes to form a metal vertical bit line 225. The tungsten is deposited by using any suitable deposition processes, such as chemical vapor deposition (CVD) reaction with tungsten hexafluoride (WF6) plus hydrogen (H2) and silane (SiH4). The metal bit lines 225 reduces the bit line resistance compared with the other embodiment using semiconductor bit line such as bit line 205 shown in FIG. 4C.

FIG. 8G shows how the first sacrificial layer 213 is selectively removed by using an isotropic etching process, such as wet etching. If the first sacrificial layer 213 is formed of silicon oxide (SiO2), it is etched by using buffered hydrofluoric acid (HF) with ammonium fluoride (NH4F) or a mixture of hydrofluoric acid (HF) and nitric acid (HNO3).

FIG. 8H shows how a high melting point metal, such as tungsten (W) or heavily doped polysilicon is deposited to fill the space that was previously occupied by the first sacrificial layer 213 to form a source lines 226. The tungsten is deposited by using any suitable deposition processes, such as chemical vapor deposition (CVD) reaction with tungsten hexafluoride (WF6) plus hydrogen (H2) and silane (SiH4).

FIG. 8I shows how the second sacrificial layer 214 is selectively removed by using an isotropic etching process, such as wet etching.

FIG. 8J shows how a gate dielectric layer 206 is formed on the exposed surfaces of the source line 226 and semiconductor layer 223 and within the space that was previously occupied by the second sacrificial layer 214.

FIG. 8K shows how the space defined by the dielectric layer 206 is filled with metal or heavily doped polysilicon to form gate 207. The process steps shown in FIGS. 8I-K are as the same as the steps described with reference to FIGS. 4D-F. The reader is referred to the description of FIGS. 4D-F for the detailed description of these process steps. As a result, the floating-body cell structure using a thin-film transistor is formed as shown in FIG. 8K.

FIG. 8L shows another embodiment for forming a cell structure. After the process step shown in FIG. 8I is performed, the process steps shown in FIGS. 4G-H are performed to form a charge-trapping layer 208 and gate 207 as illustrated in FIG. 8L. The reader is referred to the description of FIGS. 4G-H for the detailed description for forming the charge-trapping layer 208 and gate 207. This embodiment forms a NOR-type flash memory cell based on a thin-film transistor as shown in FIG. 8L.

In another embodiment, the charge-trapping layer 208 shown in FIG. 8L is replaced with a non-volatile memory gate dielectric layer formed using the materials described with reference to FIGS. 2C-D to form the cell embodiments of FRAM, RRAM, MRAM, or PCM. The reader is referred to the description of FIGS. 2C-D for the detailed descriptions for forming the non-volatile memory gate dielectric layers 170a and 170b.

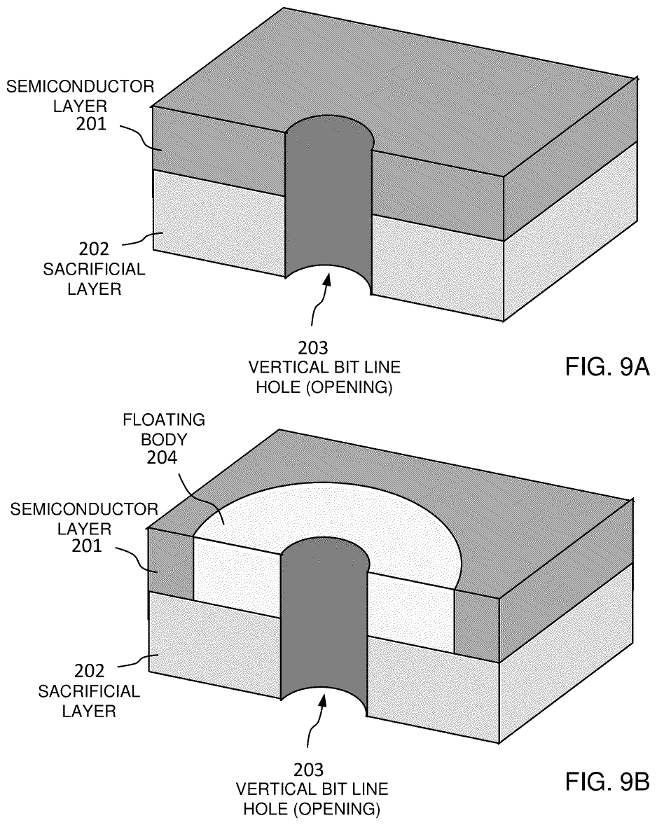

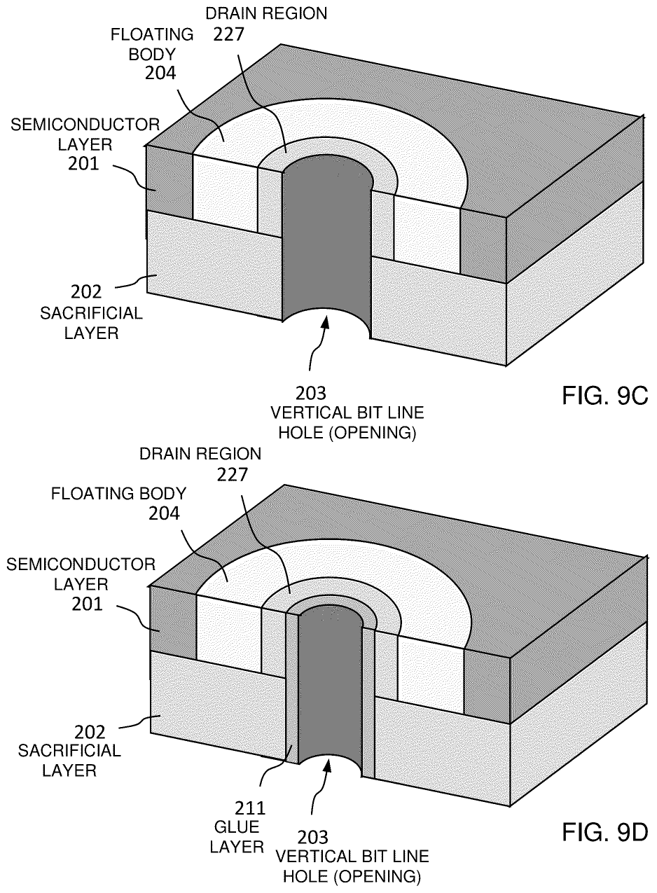

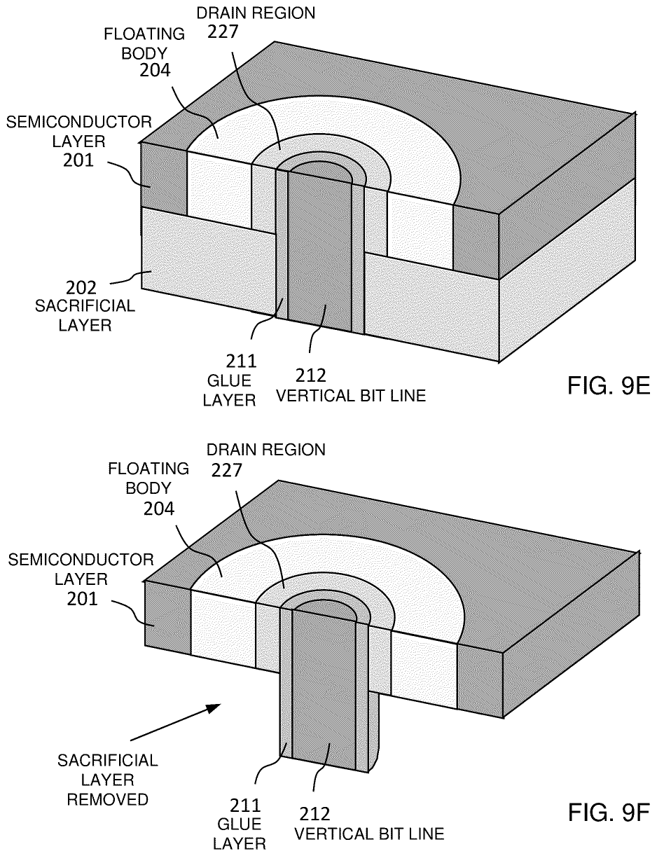

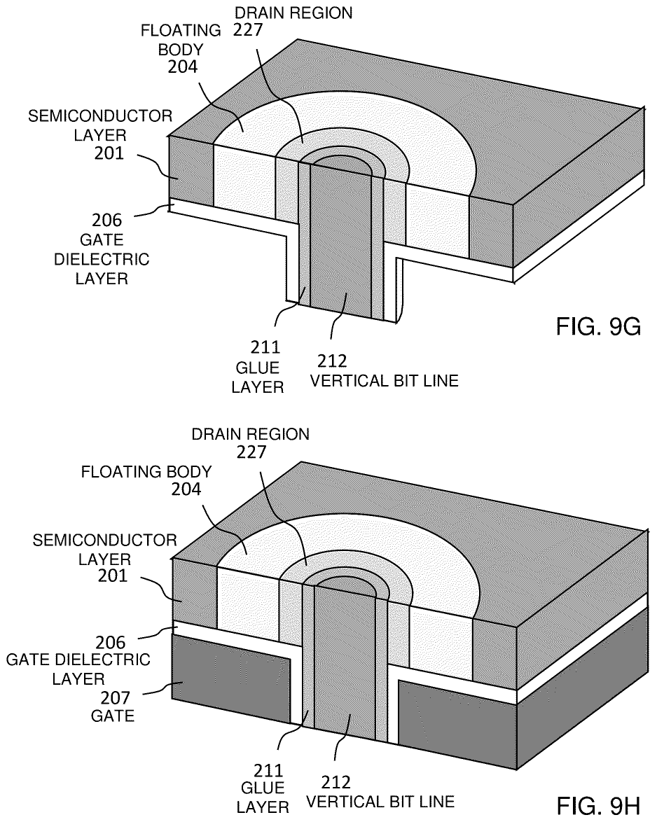

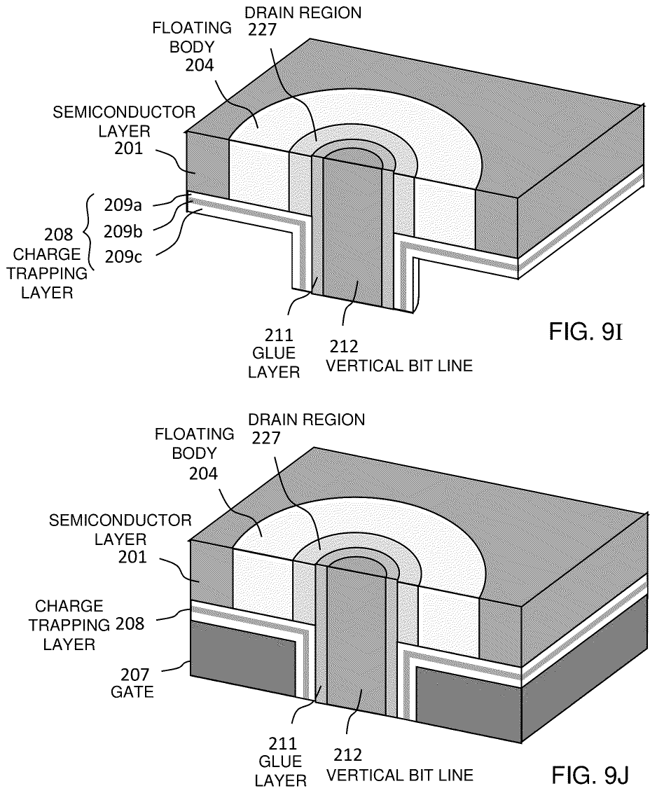

FIGS. 9A-J show another embodiment of brief process steps to form the cell structure shown in FIGS. 1E-F according to the invention. This embodiment is similar to the embodiment shown in FIGS. 5A-J except that a drain region 227 shown in FIG. 9C is formed by using a different process than the process used to form the semiconductor layer 210 shown in FIG. 5C.

FIGS. 9A-B show the formation of the semiconductor layer 201, sacrificial layer 202, vertical bit line hole 203 and floating body 204, which are formed in accordance with the process steps shown and described with reference to FIGS. 5A-B.

FIG. 9C shows how the drain region 227 is formed by using plasma doping (PLAD) or any other suitable doping processes, performed through the vertical bit line holes 203, to dope the floating body 204 with the opposite type of heavy dopants as used in the floating body 204. For NMOS cells, phosphine (PH3) or Arsine (AsH3) plasma is used to implant phosphorus or Arsenic ions into the P-type floating body 204 to reverse the doping to form an N+drain region 227. For PMOS cells, diborane and hydrogen (B2H6/H2) plasma are used to implant boron ions into the N-type floating body 204 to reverse the doping to form a P+ drain region 227.

FIGS. 9D-J show how various cell structures are formed using the same processes as shown and described with reference to FIGS. 5D-J. The reader is referred to the description of FIGS. 5D-J for the detailed description of the process steps performed and shown in FIGS. 9D-J.

In another embodiment, the process step shown in FIG. 9C for forming the drain region 227 can be applied to all the other embodiments shown in FIGS. 4A-8L.

In another embodiment, the charge-trapping layer 208 shown in FIG. 9J is replaced with a non-volatile memory gate dielectric layer using the materials and process steps described in FIG. 2C-D to form the cell embodiments of FRAM, RRAM, MRAM, or PCM. The reader is referred to FIG. 2C-D for the detailed descriptions for forming the non-volatile memory gate dielectric layers 170a and 170b.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A method of forming a memory cell structure, comprising:
alternately depositing first sacrificial layers and second sacrificial layers having different etching selectivities to form a multilayer stack;
forming vertical openings through the multilayer stack using a deep-trench etching process;
performing an isotropic etching process through the openings to selectively remove portions of the first sacrificial layers such that lateral recesses between the second sacrificial layers are formed;
depositing semiconductor material to fill the recesses and the openings such that the semiconductor material in the recesses defines junction-less floating-body channel regions and the semiconductor material in the openings defines vertical semiconductor regions continuous through the stack;
etching the deposited semiconductor material anisotropically using the second sacrificial layers as a hard mask to generate re-formed vertical openings while retaining the semiconductor material in the recesses;
filling the re-formed vertical openings with conductor material to provide vertical bit lines in contact with the junction-less floating-body channel regions;
removing the first sacrificial layers to form first spaces previously occupied by the first sacrificial layers;
filling the first spaces with conductor material to form a source line layer disposed in the first spaces;
removing the second sacrificial layers to form second spaces previously occupied by the second sacrificial layers adjacent to the channel regions; and
forming gate dielectric and gate conductor material in the second spaces previously occupied by the second sacrificial layers so as to surround the junction-less floating-body channel regions.

2. The method of claim 1, wherein the isotropic etching process comprises a wet etching process.

3. The method of claim 1, wherein the gate dielectric layer comprises a material structure selected from the group consisting of: (i) a thin oxide layer, (ii) a high-K material layer, (iii) charge-trapping layers, (iv) a ferroelectric layer, (v) an adjustable resistive layer, (vi) a phase-change layer, and (vii) a magnetoresistive stack comprising at least one ferromagnetic layer and a tunnel-barrier layer.

4. The method of claim 3, wherein the gate dielectric layer comprises the thin oxide layer or the high-K material layer, and wherein the high-K material layer comprises one of hafnium oxide (HfO₂), zirconium oxide (ZrO₂), and titanium oxide (TiO₂).

5. The method of claim 3, wherein the gate dielectric layer comprises the charge-trapping layers, and wherein the charge-trapping layers comprise one of oxide-nitride-oxide (ONO) layers, oxide-nitride (ON) layers, and oxide-nitride-oxide-nitride-oxide (ONONO) layers.

6. The method of claim 3, wherein the gate dielectric layer comprises the ferroelectric layer, and wherein the ferroelectric layer comprises one of lead zirconate titanate (PZT), hafnium oxide (HfO₂) in orthorhombic crystal phase, and hafnium zirconium oxide (HfZrO₂).

7. The method of claim 3, wherein the gate dielectric layer comprises the adjustable resistive layer, and wherein the adjustable resistive layer comprises one of hafnium oxide (HfOₓ), titanium oxide (TiOₓ), and tantalum oxide (TaOₓ).

8. The method of claim 3, wherein the gate dielectric layer comprises (i) the phase-change layer or (ii) the magnetoresistive stack, wherein the phase-change layer comprises Germanium Antimony Tellurium alloy or chalcogenide glass Ge₂Sb₂Te₅ (GST), and wherein the magnetoresistive stack comprises a first ferromagnetic layer, a second ferromagnetic layer, and the tunnel-barrier layer between the first and second ferromagnetic layers, and wherein each of the first and second ferromagnetic layers comprises one of an iron-nickel (NiFe) alloy or an iron-cobalt (CoFe) alloy and wherein the tunnel-barrier layer comprises hafnium oxide (HfO₂).

9. The method of claim 1, wherein the gate material comprises one of metal or heavily doped polysilicon.

10. The method of claim 1, wherein the bit line material comprises one of metal or polysilicon.

11. The method of claim 1, wherein the gate dielectric layer is formed using one of atomic layer deposition (ALD), plasma-enhanced atomic layer deposition (PE-ALD), thermal oxidation, or dry oxidation.

12. The method of claim 1, wherein the isotropic etching process selectively removes the first sacrificial layers relative to the second sacrificial layers such that the lateral recesses are formed without substantially etching the second sacrificial layers.

13. The method of claim 1, wherein the semiconductor material deposited to fill the recesses and the openings comprises one of amorphous silicon, polysilicon, or monocrystalline silicon.

14. The method of claim 1, wherein depositing the semiconductor material comprises a conformal deposition process such that the semiconductor material in the lateral recesses forms laterally-extending channel regions having a thickness defined by a recess depth.

15. The method of claim 1, wherein etching the deposited semiconductor material anisotropically comprises a reactive-ion etching process configured to clear the semiconductor material from the openings while retaining the semiconductor material within the lateral recesses.

16. The method of claim 1, wherein the conductor material comprises (i) a high melting point metal selected from tungsten (W), tantalum (Ta), titanium (Ti), niobium (Nb), and ruthenium (Ru), or (ii) a metal nitride selected from WN, TaN, and TiN.

17. The method of claim 1, wherein filling the re-formed vertical openings with the conductor material comprises depositing the conductor material to fill the re-formed vertical openings.

18. The method of claim 1, wherein removing the second sacrificial layers forms spaces surrounding the junction-less floating-body channel regions, and wherein forming the gate dielectric and gate conductor material comprises conformally forming a gate-all-around structure around each channel region.

19. The method of claim 1, wherein the gate conductor material formed in the second spaces defines a plurality of laterally-extending gate electrodes arranged at different vertical levels of the multilayer stack.

20. The method of claim 19, wherein the memory cell structure comprises a plurality of the junction-less floating-body channel regions stacked at different vertical levels and coupled to a corresponding plurality of the gate electrodes to form a three-dimensional array of memory cells.
